(19) United States
(12) Patent Application Publication
(10) Pub. No.: US 2025/0006719 A1
(43) Pub. Date: Jan. 2, 2025

(54) ANTENNA MODULES WITH PARTIALLY OVERLAPPING STACKED CIRCUITS

(71) Applicant: Intel Corporation, Santa Clara, CA (US)

(72) Inventors: Georgios Panagopoulos, Munich (DE); Richard Geiger, Munich (DE); Steven Callender, Denver, CO (US); Georgios Dogiamis, Chandler, AZ (US); Manisha Dutta, Munich (DE); Stefano Pellerano, Beaverton, OR (US)

(73) Assignee: Intel Corporation, Santa Clara, CA (US)

(21) Appl. No.: 18/341,875

(22) Filed: Jun. 27, 2023

(51) Int. Cl. H01L 25/18; H01L 23/00; H01Q 1/22; H01Q 23/00

(52) U.S. Cl. CPC H01L 25/18; H01L 24/08; H01L 24/16; H01Q 1/2283; H01Q 23/00; H01L 24/06; H01L 2224/0557; H01L 2224/06181; H01L 2224/08145; H01L 2224/16145

(57) ABSTRACT

Example antenna module includes antenna units provided over an antenna unit support, and ICs communicatively coupled to various antenna units. The ICs are arranged in two or more subsets of one or more ICs in each subset, where an individual IC belongs to only one subset, different subsets are in different layers with respect to the antenna unit support, and an average pitch of projections of all of the ICs onto a plane parallel to the antenna unit support is substantially equal to, or smaller, than an average pitch of the antenna units. When an average width of the ICs is larger than the average pitch of the antenna units, arranging the ICs in two or more subsets in different layers means that at least one of the ICs of one subset partially overlaps with at least one of the ICs of another subset.

### BACKGROUND

Wireless communication devices, such as handheld computing devices and wireless access points, include antennas. The frequencies over which communication may occur may depend on the shape and arrangement of the antennas, among other factors.

### BRIEF DESCRIPTION OF THE DRAWINGS

Embodiments will be readily understood by the following detailed description in conjunction with the accompanying drawings.

FIG. 1 is a side, cross-sectional view of an antenna module, in accordance with various embodiments.

FIGS. 2-4 are side, cross-sectional views of example antenna boards, in accordance with various embodiments.

FIG. 5 is a bottom view of an example antenna unit, in accordance with various embodiments.

FIG. 6 is a side, cross-sectional view illustrating details of an example integrated circuit (IC) arrangement of an antenna module, in accordance with an embodiment.

FIG. 7 is a top-down view of the antenna module of FIG. 6, in accordance with an embodiment.

FIGS. 8-11 are side, cross-sectional views of portions of other example IC arrangements of an antenna module, in accordance with various embodiments.

FIG. 12 is a top-down view of yet another example IC arrangement of an antenna module, in accordance with an embodiment.

FIGS. 13A-13D are top-down views of different layers of the antenna module of FIG. 12, in accordance with an embodiment.

FIGS. 14-16 are side, cross-sectional views illustrating details of different example IC packages of an antenna module, in accordance with various embodiments.

FIG. 17 is a perspective view of a handheld communication device including an IC package with one or more antenna modules, in accordance with various embodiments.

FIG. 18 is a perspective view of a laptop communication device including multiple IC packages with one or more antenna modules, in accordance with various embodiments.

FIG. 19 is a top view of a wafer and dies that may be included in an antenna module, in accordance with any of the embodiments disclosed herein.

FIG. 20 is a side, cross-sectional view of an IC device that may be included in an antenna module, in accordance with any of the embodiments disclosed herein.

FIG. 21 is a side, cross-sectional view of an IC device assembly that may include one or more antenna modules, in accordance with any of the embodiments disclosed herein.

FIG. 22 is a block diagram of an example communication device that may include one or more antenna modules, in accordance with any of the embodiments disclosed herein.

FIG. 23 is a block diagram of an example radio frequency (RF) device that may include one or more antenna modules, in accordance with any of the embodiments disclosed herein.

### DETAILED DESCRIPTION

The systems, methods and devices of this disclosure each have several innovative aspects, no single one of which is solely responsible for all of the desirable attributes disclosed herein. Details of one or more implementations of the subject matter described in this specification are set forth in the description below and the accompanying drawings.

For purposes of illustrating antenna modules proposed herein, it might be useful to first understand phenomena that may come into play in some systems where antenna modules may be used. The following foundational information may be viewed as a basis from which the present disclosure may be properly explained. Such information is offered for purposes of explanation only and, accordingly, should not be construed in any way to limit the broad scope of the present disclosure and its potential applications.

In context of radio systems, an antenna is a device that serves as an interface between radio waves propagating wirelessly through space and electric currents moving in conductive interconnect structures (e.g., conductive lines and conductive vias) used with a transmitter or receiver. During transmission, a transmitter supplies an electric current to the antenna's terminals, and the antenna radiates the energy from the current as radio waves. During reception, an antenna intercepts some of the power of a radio wave in order to produce an electric current at its terminals, which current is subsequently applied to a receiver to be amplified. A transceiver is a device that includes circuitry of both a transmitter and a receiver. Antennas are essential components of all radio equipment, and are used in radio broadcasting, broadcast television, two-way radio, communications receivers, radar, cell phones, satellite communications and other devices.

An antenna with a single antenna unit typically broadcasts a radiation pattern that radiates equally in all directions in a spherical wavefront. A phased array (also sometimes referred to as a “phased array antenna”) refers to an array of antenna units used to focus electromagnetic energy in a particular direction, thereby creating a main beam. Phased arrays offer numerous advantages over antennas with single antenna units, such as increased gain and ability to perform directional steering. Therefore, phased arrays are used in many applications, with cellular/wireless mobile technology being a prominent example.

Antenna dimensions and pitch are inversely proportional to a frequency of operation (e.g., a frequency of wireless signals transmitted and/or received by antennas). Therefore, as the frequency increases into millimeter wave, sub-Terahertz (THz), and THz regions, antenna dimensions become small enough to consider integration of antenna arrays (e.g., phased arrays) within IC packages and on die. In fact, antenna integration in a single package with one or more ICs used to control operation of the antennas (e.g., ICs comprising RF transceiver circuitry) is critical for millimeter wave, sub-THz, and THz wireless communication systems. At these frequencies, the output power of semiconductor devices (e.g., transistors) used in the ICs decreases substantially, necessitating an increase in the number of antenna units in an array. Increasing the number of antenna units in an array advantageously leads to higher emitted power, reduced loss by increased directivity, and increased signal-to-noise ratio (SNR) on the receiver side.

However, oftentimes each antenna unit requires its own signal chain with power amplifiers, low-noise amplifiers, local oscillator (i.e., clock) distribution, phase shifters, and other circuitry. Therefore, situations may arise where the size of an IC for controlling operation of a given antenna unit of an array is greater than a pitch of the antenna units in the array, especially as the frequency of operation increases and antenna pitch correspondingly decreases. In such situations, antenna units may not be placed as closely to one another as desired, e.g., at a pitch approximately equal to half of a wavelength at the frequency of operation. This is one of the recognized problems for next generation communication systems. This problem has triggered a significant amount of research on designing more compact ICs (e.g., ICs with more compact power amplifiers), but could also limit the scaling of antenna arrays or power levels per element.

Some conventional solutions to the problem of control ICs being larger than the pitch of antenna units feature large fanout schemes for routing of signals between the ICs and corresponding antenna units of an array. The IC output ports have larger pitch than the antenna array at these frequencies and, thus, require additional and cumbersome routing at package level to feed the RF signal from the transceiver elements of the ICs to the input ports of the antenna. The additional routing caused by the mismatch in pitch between ICs and antenna units may cause large insertion losses in the RF path, decreasing transmitted power and SNR.

Disclosed herein are antenna modules, electronic assemblies, and communication devices that aim to improve on one or more challenges described above. An example antenna module includes a plurality of antenna units provided over the antenna unit support, and a plurality of ICs communicatively coupled to various antenna units. The ICs are arranged in two or more subsets of one or more ICs in each subset, where an individual IC belongs to only one subset, different subsets are in different layers with respect to the antenna unit support, and an average pitch of projections of all of the ICs onto a plane parallel to the antenna unit support is substantially equal to, or smaller, than an average pitch of the antenna units. When an average width of the ICs is larger than the average pitch of the antenna units, arranging the ICs in two or more subsets in different layers means that at least one of the ICs of one subset partially overlaps with at least one of the ICs of another subset. Hence, such an antenna module may be referred to as an “antenna module with partially overlapping stacked circuits.”

In context of the present disclosure, ICs communicatively coupled to the antenna units and provided in two or more subsets in different layers with respect to the antenna unit support refer to ICs that include active circuitry for controlling operation of the antenna units (e.g., there may be one-to-one correspondence between the ICs and the antenna units, where each IC includes active circuitry for controlling operation of one of the antenna units). In some embodiments, such an IC may include RF transceiver circuitry associated with an antenna unit, such as transmit (TX) path amplifier (e.g., a power amplifier), receive (RX) path amplifier (e.g., a low-noise amplifier), TX path post-mix filter, RX path pre-mix filter, RF switch, RF mixer, etc. In some embodiments, such an IC may include RF circuitry of only TX path or only RX path. In some embodiments, such an IC may include at least portions of low-frequency circuitry, such as circuitry used in the TX path before frequency upconversion from a lower frequency (e.g., frequency below about 300 Hz) to the RF and/or circuitry used in the RX path after frequency downconversion from the RF to the lower frequency (e.g., local oscillator generation circuits, baseband or intermediate frequency (IF) circuits, amplifiers, filters, power management circuits).

Various ones of the antenna modules disclosed herein may exhibit improved performance to enable millimeter wave, sub-THz, and THz operation in mobile devices and other electronic device environments. For example, the antenna modules disclosed herein may help achieve broad bandwidth operation with high return loss and high gain. In another examples, the low cost, high yield techniques and designs disclosed herein may allow improving impedance bandwidth and radiation efficiency over the operational bandwidth. Further various ones of the antenna modules disclosed herein may exhibit little to no warpage during operation or installation, ease of assembly, low cost, fast time to market, and/or good mechanical handling. The antenna modules disclosed herein may be advantageously included in mobile devices, base stations, access points, routers, backhaul communication links, and other communication devices.

In the following detailed description, reference is made to the accompanying drawings that form a part hereof wherein like numerals designate like parts throughout, and in which is shown, by way of illustration, embodiments that may be practiced. It is to be understood that other embodiments may be utilized, and structural or logical changes may be made, without departing from the scope of the present disclosure. Therefore, the following detailed description is not to be taken in a limiting sense.

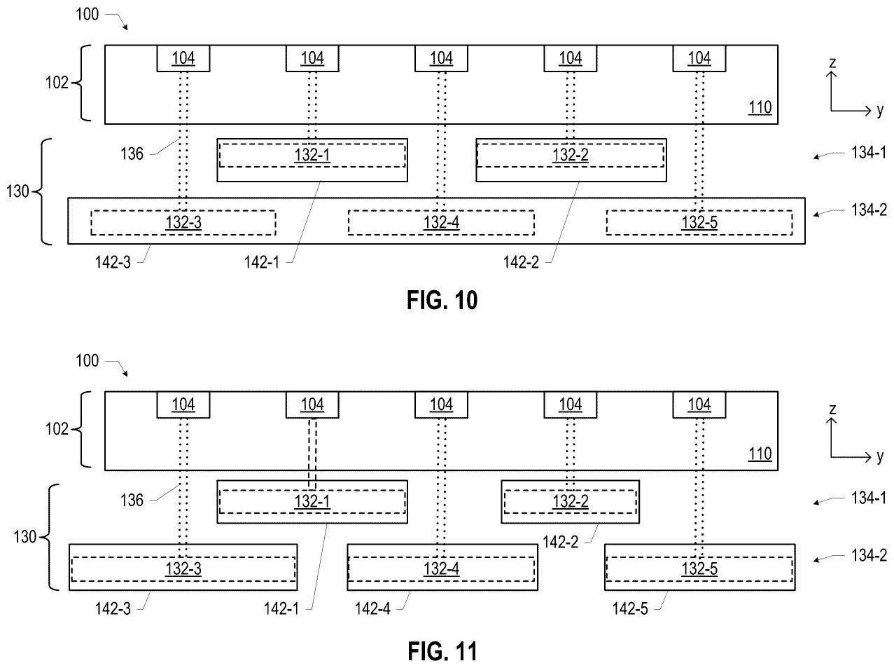

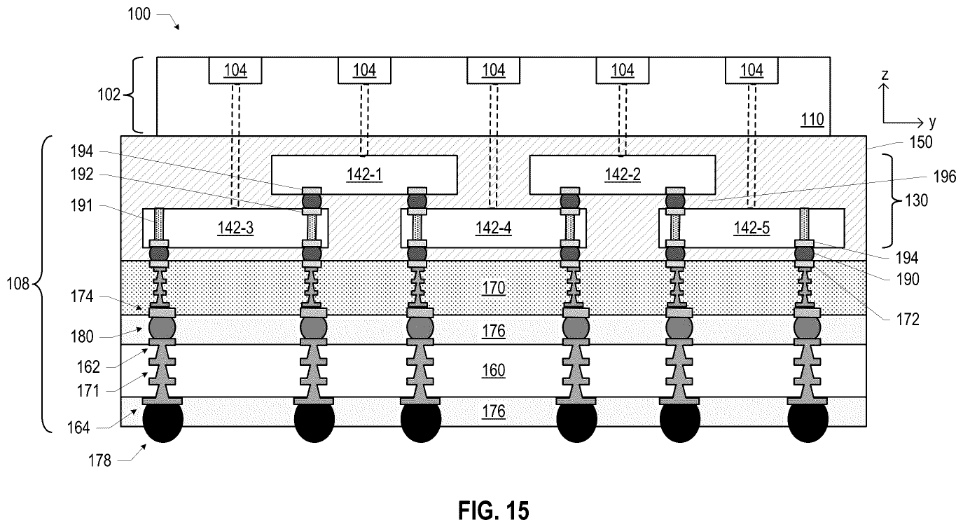

Any of the features discussed with reference to any of accompanying drawings herein may be combined with any other features to form an antenna module 100, an IC package 108, or a communication device 210/220, as appropriate. For convenience, the phrase “ICs 132” may be used to refer to a collection of ICs 132-1, 132-2, and so on, the phrase “IC dies 142” may be used to refer to a collection of IC dies 142-1, 142-2, and so on, etc. A collection of drawings labeled with different letters may be referred to without the letters, e.g., a collection of FIGS. 13A-13D may be referred to as “FIG. 13.” A number of elements of the drawings with same reference numerals may be shared between different drawings; for ease of discussion, a description of these elements provided with respect to one of the drawings is not repeated for the other drawings, and these elements may take the form of any of the embodiments disclosed herein. To not clutter the drawings, if multiple instances of certain elements are illustrated, only some of the elements may be labeled with a reference numeral (e.g., five communicatively coupled connections 136 are shown in FIG. 6 but only one of the them is labeled with a reference numeral). Also to not clutter the drawings, not all reference numerals shown in one of the drawings are shown in other similar drawings. The drawings are not necessarily to scale. Although many of the drawings illustrate rectilinear structures with flat walls and right-angle corners, this is simply for ease of illustration and may not reflect real-life process limitations which may cause various features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers. There may be other defects not listed here but that are common within the field of semiconductor device fabrication and packaging. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of antenna modules as described herein.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). When used to describe a range of dimensions, the phrase “between X and Y” represents a range that includes X and Y. When used to describe a location of an element, the phrase “between X and Y” represents a region that is spatially between element X and element Y. The terms “substantially,” “close,” “approximately,” “near,” and “about,” generally refer to being within +/−20%, e.g., within +/−5% or within +/−2%, of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−10%, e.g., within +/−5% or within +/−2%, of the exact orientation.

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. As used herein, the terms “package” and “IC package” are synonymous, as are the terms “die” and “IC die.” Furthermore, the terms “chip,” “chiplet,” “die,” and “IC die” may be used interchangeably herein.

Although certain elements may be referred to in the singular herein, such elements may include multiple sub-elements. For example, “a dielectric material” may include one or more dielectric materials or “an insulator material” may include one or more insulator materials. The terms “oxide,” “carbide,” “nitride,” etc. refer to compounds containing, respectively, oxygen, carbon, nitrogen, etc. The term “high-k dielectric” refers to a material having a higher dielectric constant than silicon oxide, while the term “low-k dielectric” refers to a material having a lower dielectric constant than silicon oxide. The term “insulating” and variations thereof (e.g., “insulative” or “insulator”) means “electrically insulating,” the term “conducting” and variations thereof (e.g., “conductive” or “conductor”) means “electrically conducting,” unless otherwise specified. With reference to optical signals and/or devices, components and elements that operate on or using optical signals, the term “conducting” can also mean “optically conducting.” The term “insulating material” refers to solid materials (and/or liquid materials that solidify after processing as described herein) that are substantially electrically nonconducting. They may include, as examples and not as limitations, organic polymers and plastics, and inorganic materials such as ionic crystals, porcelain, glass, silicon and alumina or a combination thereof. They may include dielectric materials, high polarizability materials, and/or piezoelectric materials. They may be transparent or opaque without departing from the scope of the present disclosure. Further examples of insulating materials are underfills and molds or mold-like materials used in packaging applications, including for example, materials used in organic interposers, package supports and other such components.

In a general sense, an “interconnect structure” or, simply, an “interconnect” refers to any element that provides a physical connection between two other elements. For example, an electrical interconnect provides electrical connectivity between two electrical components, facilitating communication of electrical signals between them; an optical interconnect provides optical connectivity between two optical components, facilitating communication of optical signals between them. As used herein, both electrical interconnects and optical interconnects are comprised in the term “interconnect.” The nature of the interconnect being described is to be understood herein with reference to the signal medium associated therewith. Thus, when used with reference to an electronic device, such as an IC that operates using electrical signals, the term “interconnect” describes any element formed of an electrically conductive material for providing electrical connectivity to one or more elements associated with the IC or/and between various such elements. Likewise, when used with reference to a device that operates on optical signals as well, such as a photonic IC (PIC), “interconnect” may also describe any element formed of a material that is optically conductive for providing optical connectivity to one or more elements associated with the PCI. In such cases, the term “interconnect” may refer to optical waveguides (e.g., structures that guide and confine light waves), including optical fiber, optical splitters, optical combiners, optical couplers, and optical vias.

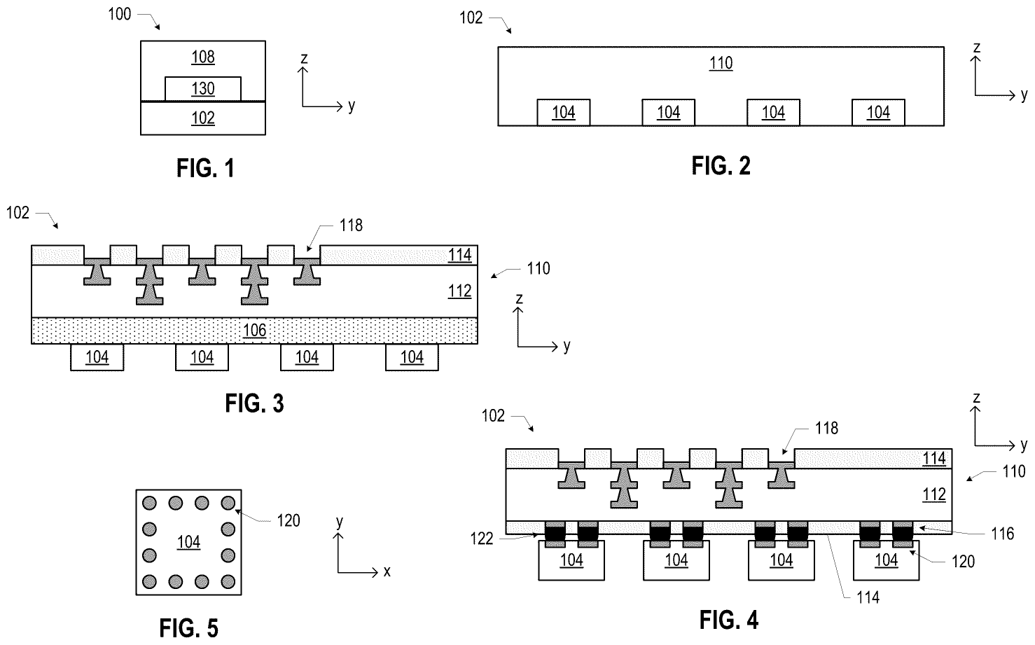

FIG. 1 is a side, cross-sectional view of an antenna module 100, in accordance with various embodiments. The antenna module 100 may include an IC package 108 coupled to an antenna board 102. Although a single IC package 108 is illustrated in FIG. 1, an antenna module 100 may include more than one IC package 108. The antenna board 102 may include conductive pathways (e.g., provided by conductive vias and lines through one or more dielectric materials) and RF transmission structures (e.g., antenna feed structures, such as striplines, microstrip lines, or coplanar waveguides) that may enable one or more antenna units 104 (not shown in FIG. 1 but shown in subsequent drawings) to transmit and receive electromagnetic waves under the control of circuitry in the IC package 108. To that end, the IC package 108 may include an IC arrangement 130, comprising a plurality of ICs having circuitry to control the antenna units 104 of the antenna board 102. In particular, the IC arrangement 130 may include ICs arranged in two or more subsets of one or more ICs in each subset, where an individual IC belongs to only one subset, different subsets are in different layers with respect to the antenna unit support, and an average pitch of projections of all of the ICs onto a plane parallel to the antenna unit support is substantially equal to, or smaller, than an average pitch of the antenna units 104, as discussed below with reference to FIGS. 6-13. In some embodiments, the antenna module 100 may include a different IC of the IC arrangement 130 for controlling each different antenna unit 104; in other embodiments, the IC arrangement 130 of the antenna module 100 may include one IC having circuitry to control multiple antenna units 104. In some embodiments, at least a portion of the antenna board 102 may be fabricated using printed circuit board (PCB) technology, and may include between two and eight PCB layers. In other embodiments, at least a portion of the antenna board 102 may include other materials, such as silicon or any other semiconductor material, glass, quartz, alumina, etc. In some embodiments, the antenna board 102 may be, or may include, a glass core. As used herein, the term “glass core” refers to a structure (e.g., a portion of a glass layer) of any glass material such as quartz, silica, fused silica, silicate glass (e.g., borosilicate, aluminosilicate, alumino-borosilicate), soda-lime glass, soda-lime silica, borofloat glass, lead borate glass, photosensitive glass, non-photosensitive glass, or ceramic glass. In particular, the glass core may refer to bulk glass or a solid volume of glass, as opposed to, e.g., materials that may include particles of glass, such as glass fiber reinforced polymers. Such glass materials are typically non-crystalline, often transparent, amorphous solids. In some embodiments, a glass core may be an amorphous solid glass layer. In some embodiments, a glass core may include silicon and oxygen, as well as any one or more of aluminum, boron, magnesium, calcium, barium, tin, sodium, potassium, strontium, phosphorus, zirconium, lithium, titanium, and zinc. In some embodiments, a glass core may include a material, e.g., any of the materials described above, with a weight percentage of silicon being at least about 0.5%, e.g., between about 0.5% and 50%, between about 1% and 48%, or at least about 23%. For example, if a glass core is fused silica, the weight percentage of silicon may be about 47%. In some embodiments, a glass core may include at least 23% silicon and at least 26% oxygen by weight, and, in some further embodiments, such a glass core may further include at least 5% aluminum by weight. In some embodiments, a glass core may include any of the materials described above and may further include one or more additives such as Al2O3, B2O3, MgO, CaO, SrO, BaO, SnO2, Na2O, K2O, SrO, P2O3, ZrO2, Li2O, Ti, and Zn.

Examples of IC arrangements 130, IC packages 108, and antenna boards 102 are discussed in detail below. In some embodiments, the total z-height of an antenna module 100 may be less than 3 millimeters (e.g., between 2 millimeters and 3 millimeters).

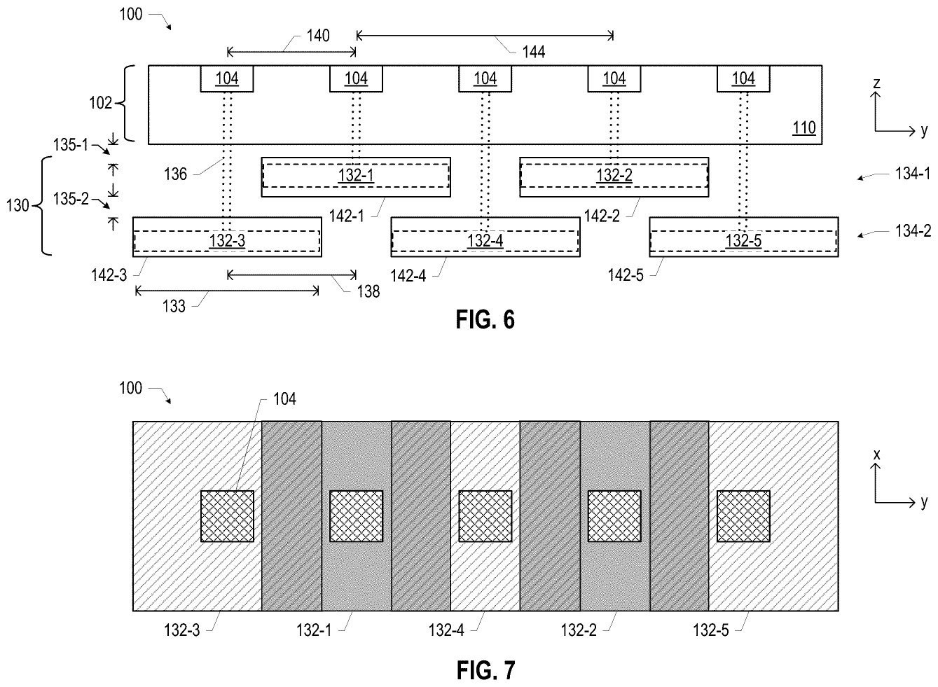

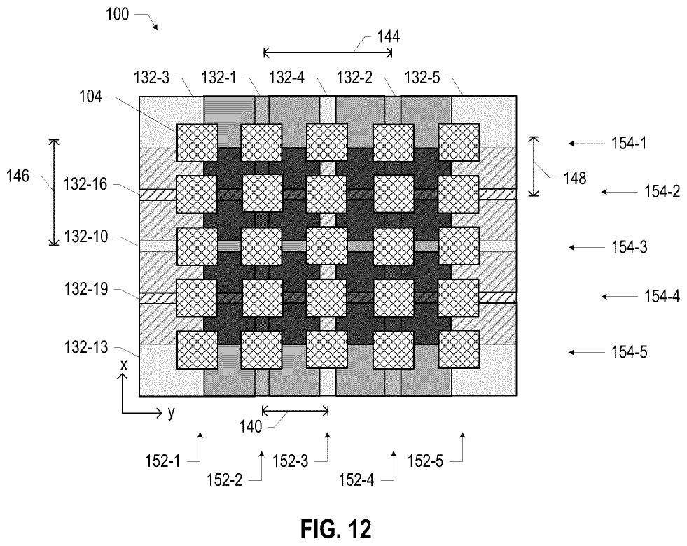

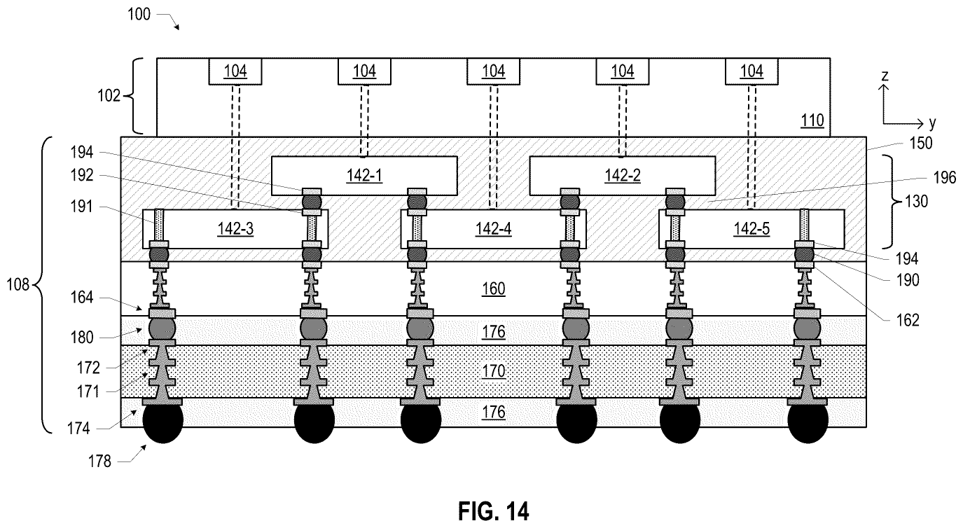

FIGS. 2-4 are side, cross-sectional views of example antenna boards 102, in accordance with various embodiments. FIG. 2 is a generalized representation of an example antenna board 102 including one or more antenna units 104 coupled to an antenna unit support 110. In some embodiments, the antenna units 104 may be electrically coupled to the antenna unit support 110 by electrically conductive material pathways through the antenna unit support 110 that makes conductive contact with electrically conductive material of the antenna units 104, while in other embodiments, the antenna units 104 may be mechanically coupled to the antenna unit support 110 but may not be in contact with an electrically conductive material pathway through the antenna unit support 110. In some embodiments, at least a portion of the antenna unit support 110 may be fabricated using PCB technology, and may include between two and eight PCB layers. Although a particular number of antenna units 104 is depicted in FIG. 2 (and others of the accompanying drawings), this is simply illustrative, and an antenna board 102 may include fewer or more antenna units 104. For example, in some embodiments, an antenna board 102 may include five antenna units 104 (e.g., arranged in a linear array, as discussed below with reference to FIGS. 6-7), while, in other embodiments, an antenna board 102 may include twenty-five antenna units 104 (e.g., arranged in a 5×5 array, as discussed below with reference to FIGS. 12-13). In some embodiments, the antenna units 104 may be surface mount components.

In some embodiments, an antenna module 100 may include one or more arrays of antenna units 104 to support multiple communication bands (e.g., dual band operation or tri-band operation). For example, in some embodiments, the antenna module 100 may support tri-band operation at 28 gigahertz (GHz), 39 GHZ, and 60 GHz. In other embodiments, the antenna module 100 may support tri-band operation at 24.5 GHz to 29 GHZ, 37 GHz to 43 GHz, and 57 GHz to 71 GHZ. Various ones of the antenna modules 100 disclosed herein may support 5G/6G communications and sub-THz (>100 GHz) communications. Various ones of the antenna modules 100 disclosed herein may support 28 GHz and 39 GHz communications. Various ones of the antenna modules 100 disclosed herein may support communications above 100 GHz, e.g., 120 GHZ, 170 GHz and 220 GHz communications. Various of the antenna modules 100 disclosed herein may support millimeter wave communications. Various ones of the antenna modules 100 disclosed herein may support high band frequencies and low band frequencies. In some embodiments, different antenna units 104 may be used for bandwidth enhancement, e.g., by being designed to resonate at slightly different frequencies. Individual antenna units 104 may be of any type and/or shape. For example, in some embodiments, individual antenna units 104 may be antenna patches of any shape, such as square, rectangular, circular, oval, etc., and may be a solid or mesh structure. In some embodiments, individual antenna units 104 may be antenna patches, stacks of antenna patches, monopole or dipole antennas, slanted dipole antennas (i.e., sloper antennas), other dipole antennas, horn antennas, tapered slot antennas (e.g. Vivaldi), etc. Any conductors including, but not limited to, ink, plated metal, or liquid metal, may be used to implement individual antenna units 104.

In some embodiments, an antenna board 102 may include an antenna unit 104 coupled to an antenna unit support 110 by an adhesive. FIG. 3 illustrates an antenna board 102 in which the antenna unit support 110 includes a circuit board 112 (e.g., including between two and eight PCB layers), a solder resist 114 and conductive contacts 118 at one face of the circuit board 112, and an adhesive 106 at the opposite face of the circuit board 112. As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket). The circuit board 112 may include traces, vias, and other structures, as known in the art, formed of an electrically conductive material (e.g., a metal, such as copper). The conductive structures in the circuit board 112 may be electrically insulated from each other by a dielectric material. Any suitable dielectric material may be used (e.g., a laminate material). In some embodiments, the dielectric material may be an organic dielectric material, a fire retardant grade 4 material (FR-4), bismaleimide triazine (BT) resin, polyimide materials, glass reinforced epoxy matrix materials, or low-k and ultra low-k dielectric (e.g., carbon-doped dielectrics, fluorine-doped dielectrics, porous dielectrics, and organic polymeric dielectrics).

In the embodiment of FIG. 3, the antenna units 104 may be adhered to the adhesive 106. The adhesive 106 may be electrically non-conductive, and thus the antenna units 104 may not be electrically coupled to the circuit board 112 by an electrically conductive material pathway. In some embodiments, the adhesive 106 may be an epoxy. The thickness of the adhesive 106 may control the distance between the antenna units 104 and the proximate face of the circuit board 112. When the antenna board 102 of FIG. 3 (and others of the accompanying drawings) is used in an antenna module 100, an IC package 108 may be coupled to some of the conductive contacts 118. In some embodiments, a thickness of the circuit board 112 of FIG. 3 may be less than 1 millimeter (e.g., between 0.35 millimeters and 0.5 millimeters). In some embodiments, a thickness of an antenna unit 104 may be less than 1 millimeter (e.g., between 0.4 millimeters and 0.7 millimeters).

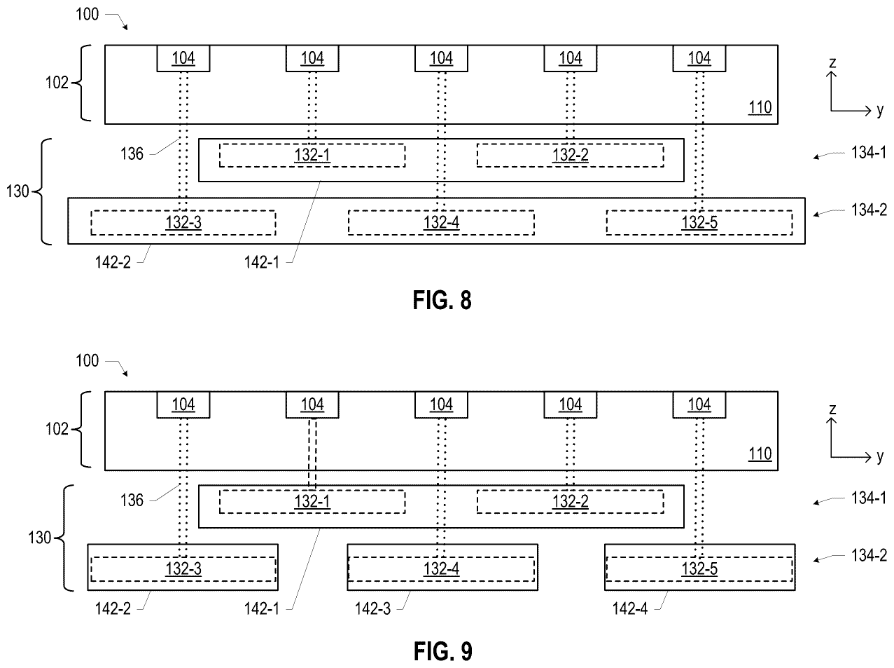

In some embodiments, an antenna board 102 may include an antenna unit 104 coupled to an antenna unit support 110 by solder. FIG. 4 illustrates an antenna board 102 in which the antenna unit support 110 includes a circuit board 112 (e.g., including between two and eight PCB layers), a solder resist 114 and conductive contacts 118 at one face of the circuit board 112, and a solder resist 114 and conductive contacts 116 at the opposite face of the circuit board 112. The antenna units 104 may be secured to the circuit board 112 by solder 122 (or other second-level interconnects) between conductive contacts 120 of the antenna units 104 and the conductive contacts 116. In some embodiments, the conductive contacts 116/solder 122/conductive contacts 120 may provide an electrically conductive material pathway through which signals may be transmitted to or from the antenna units 104. In other embodiments, the conductive contacts 116/solder 122/conductive contacts 120 may be used only for mechanical coupling between the antenna units 104 and the antenna unit support 110. The height of the solder 122 (or other interconnects) may control the distance between the antenna units 104 and the proximate face of the circuit board 112. FIG. 5 is a bottom view of an example antenna unit 104 that may be used in an antenna board 102 like the antenna board 102 of FIG. 4, in accordance with various embodiments. The antenna unit 104 of FIG. 5 may have a number of conductive contacts 120 distributed regularly on one face, close to the edges; other antenna units 104 with conductive contacts 120 may have other arrangements of the conductive contacts 120.

FIG. 6 is a side, cross-sectional view of a portion of a first example of an antenna module 100, in accordance with an embodiment. The antenna module 100 shown in FIG. 6 is a portion of the antenna module of FIG. 1 because it only illustrates a relative arrangement of an antenna board 102 and an IC arrangement 130, but not the other details of the IC package 108.

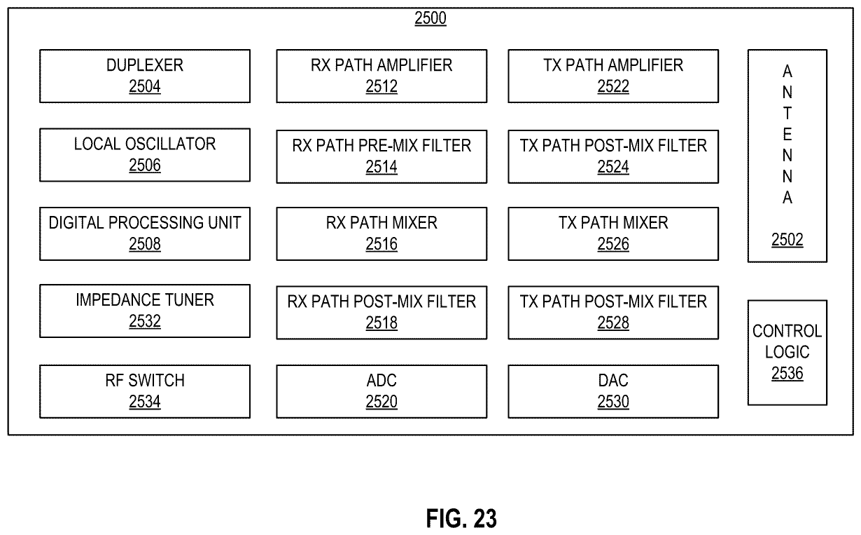

As shown in FIG. 6, the IC arrangement 130 may include a plurality of ICs 132, individually labeled as an IC 132-1, an IC 132-2, an IC 132-3, an IC 132-4, and an IC 132-5. The IC 132 may include any suitable IC components. In some embodiments, the IC 132 may include analog RF circuitry of an RF device (e.g., of the RF device 2500 of FIG. 23). For example, in some embodiments, any of the ICs 132 may include an RX path amplifier 2512 and/or a TX path amplifier 2522 of the RF device 2500 (FIG. 23). In some embodiments, one or more of the ICs 132 may include a memory device programmed with instructions to execute beam forming, scanning, and/or codebook functions. In various embodiments, the ICs 132 may include resistors, capacitors (e.g., decoupling capacitors), inductors, DC-DC converter circuitry, or other circuit elements.

The ICs 132 may be arranged in two or more subsets in different layers 134 (individually labeled in FIG. 6 as layers 134-1 and 134-2) with respect to the antenna unit support 110. For example, FIG. 6 illustrates that ICs 132-1 and 132-2 may be provides in a first layer 134-1, while ICs 132-3, 132-4, and 132-5 may be provided in a second layer 134-2. In some embodiments, a distance 135-1 between the antenna unit support 110 and the ICs 132 of the first layer 134-1 may be between about 10 nanometers and 100 micron, including all values and ranges therein, e.g., between about 10 micron and 100 micron, 100 nanometers and 10 micron, 10 nanometers and 1 micron or between about 100 nanometers and 1 micron. In some embodiments, a distance 135-2 between the ICs 132 of the first layer 134-1 and the ICs 132 of the second layer 134-2, as well as analogous distances between further layers 134 that may be present in the IC arrangement 130, may be in about the same ranges as the distance 135-1.

The ICs 132 may be communicatively coupled with different ones of the antenna units 104 by communicatively coupled connections 136, shown in FIG. 6 with dotted contours between individual ones of the ICs 132 and different ones of the antenna units 104. In some embodiments, the communicatively coupled connections 136 may include electric conductors for communicating electrical signals between the ICs 132 and associated ones of the antenna units 104. In other embodiments, the ICs 132 and associated ones of the antenna units 104 may be capacitively coupled without using any electrical conductors that communicate electrical signals between the ICs 132 and associated ones of the antenna units 104. This may be the case if, e.g., the antenna units 104 include stacked antenna patches, where a first antenna patch of a stack is provided on the surface of an IC die 142 in which a given IC 132 is provided, and the other antenna patches of the stack are capacitively coupled to the first antenna patch. Although a particular number of ICs 132, arranged in a particular number of layers 134, is depicted in FIG. 6 (and others of the accompanying drawings), this is simply illustrative, and an antenna arrangement 130 may include fewer or more ICs 132 in total, arranged in more layers 134 than two, with any number of one or more ICs 132 in each layer 134. In some embodiments, a different IC 132 may be configured for controlling each different antenna unit 104 in a one-to-one correspondence, as represented in FIG. 6 with each communicatively coupled connection 136 being between one and only one of the ICs 132 and one and only one of the antenna units 104. Such an association between the ICs 132 and the antenna units 104 as depicted in FIG. 6 (and others of the accompanying drawings) is also simply illustrative, and, in other embodiments, the number and the nature of the communicatively coupled connections 136 between the ICs 132 and the antenna units 104 may be different.

As shown in FIG. 6, at least some of the ICs 132 of different layers 134 may overlap with one another. For example, FIG. 6 illustrates that a left portion of the IC 132-1 may overlap with a right portion of the IC 132-3, while a right portion of the IC 132-1 may overlap with a left portion of the IC 132-4; in another example, FIG. 6 illustrates that a left portion of the IC 132-4 may overlap with a right portion of the IC 132-1, while a right portion of the IC 132-4 may overlap with a left portion of the IC 132-2; and so on. In general, an overlap may be present on any side of an IC 132, and a given IC 132 may have overlaps with other ICs 132, in different layers 134, on more than 2 sides. In some embodiments, the overlap may be such that, when all of the ICs 132 are projected onto some plane parallel to the antenna unit support 110 (e.g., a plane of a bottom surface or a plane of a top surface of the antenna unit support 110), and when all antenna units 104 are projected onto the same plane, an average pitch of the projections of the ICs 132 may be substantially equal to or smaller than an average pitch of the projections of the antenna units 104. As used herein, the term “pitch” refers to a center-to-center distance. For example, a pitch of antenna units 104 refers to a center-to-center distance of two nearest-neighbor antenna units 104, while a pitch of projections of the ICs 132 refers to a center-to-center distance of two nearest-neighbor projections of the ICs 132. In the context of the present disclosure, a pitch of projections of the ICs 132 is discussed, rather than a pitch of the ICs 132, because some of the ICs 132 are in different layers 134. Although the antenna units 104 are depicted in FIG. 6 (and others of the accompanying drawings) to be substantially in the same layer, this is simply illustrative, and, in other embodiments, the antenna units 104 may be arranged on or in the antenna unit support 110 in different locations along the z-axis of the example coordinate system shown in the present drawings. Therefore, a pitch of projections of the antenna units 104 is discussed, rather than a pitch of the antenna units 104, because some of the antenna units 104 may be in different layers in the antenna unit support 110. FIG. 6 illustrates a pitch 138 between projections of two nearest-neighbor ICs 132 in different layers 134. As used herein, the “average pitch of the projections of the ICs 132” refers to a result obtained by adding together pitches 138 of different nearest-neighbor overlapping projections of ICs 132 and then dividing the sum by the total number of the pitches 138 added together. FIG. 6 further illustrates a pitch 140 between projections of two nearest-neighbor antenna units 104. As used herein, the “average pitch of the projections of the ICs 132” refers to a result obtained by adding together pitches 138 of different nearest-neighbor overlapping projections of ICs 132 and then dividing the sum by the total number of the pitches 138 added together. Arranging the ICs 132 in different layers 134 advantageously enables maintaining a relatively small average pitch of their projections (e.g., an average pitch substantially equal to that of the antenna units 104) even though a width 133 of at least some of the ICs 132 may be larger than the pitch 140. In some embodiments, different ICs 132 of a given layer 134 may have a pitch 144. In some embodiments, the pitch 144 may be substantially equal to twice the pitch 138 and/or twice the pitch 140.

FIG. 7 is a top-down view of the antenna module of FIG. 6, in accordance with an embodiment, provided to further illustrate relative arrangement of the ICs 132 of different layers 134 with respect to one another and with respect to the antenna units 104. FIG. 7 depicts ICs 132 of different layers 134 using different patterns. In particular, ICs 132 of the first layer 134-1 are depicted in FIG. 7 with solid patterns and overlayed as a semi-transparent overlay over the ICs 132 of the second layer 134-2, which are shown with patterns of slanted lines. FIG. 7 further depicts antenna units 104 as an overlay over all of the ICs 132. FIG. 7 clearly illustrates how the average of the pitches 138 may be substantially equal to the average of the pitches 140.

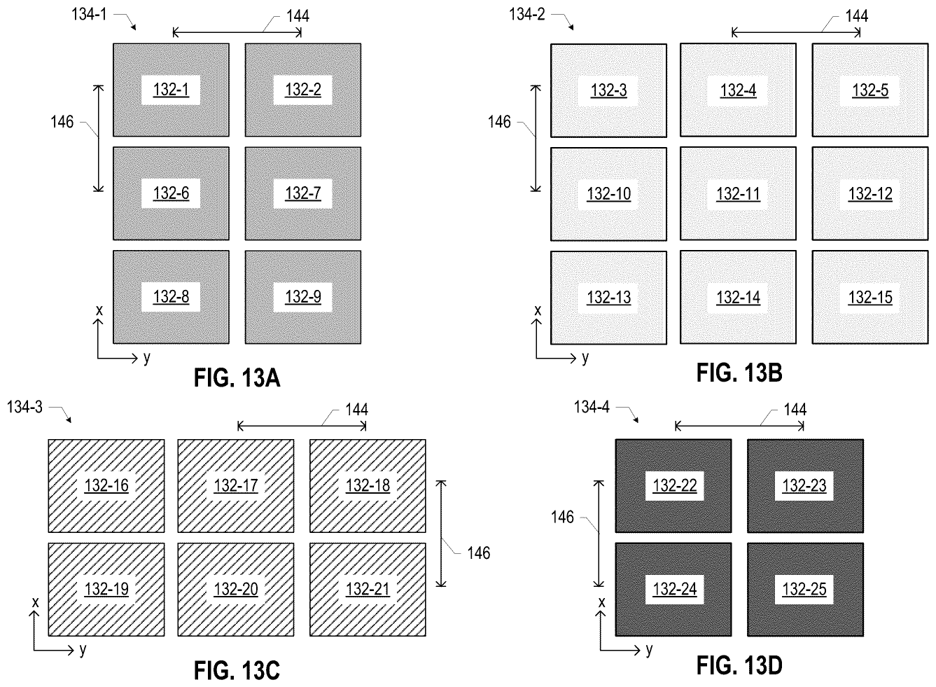

Further variations and modifications of the antenna module 100 of FIG. 6 are possible and are within the scope of the present disclosure. Each of FIGS. 8-11 illustrates a portion of an example of an antenna module 100 similar to that shown in FIG. 6, where the descriptions provided above are applicable except for the differences described below.

In some embodiments, different ICs 132 may be included in different IC dies 142 (which may also be referred to as “chiplets”). This is depicted in FIG. 6 illustrating that an IC die 142-1 may include the IC 132-1, an IC die 142-2 may include the IC 132-2, an IC die 142-3 may include the IC 132-3, an IC die 142-4 may include the IC 132-4, and an IC die 142-5 may include the IC 132-5. However, this may be different in other embodiments, e.g., as shown in the examples of FIGS. 8-10. In particular, FIG. 8 illustrates an embodiment similar to that shown in FIG. 6, except where the ICs 132 of different layers 134 are implemented on different IC dies 142, with one IC die 142 per a subset of ICs 132 of a given layer 134. Thus, FIG. 8 illustrates that an IC die 142-1 may include the ICs 132-1 and 132-2 of the first layer 134-1, while an IC die 142-2 may include the ICs 132-3, 132-4, and 132-5 of the second layer 134-1. Each of FIG. 9 and FIG. 10 illustrates an embodiment similar to that shown in FIG. 6, except where the ICs 132 of different layers 134 are implemented on different IC dies 142, with one IC die 142 per a subset of ICs 132 of one of the layers 134 and individual dies per IC 132 of another layer 134. Thus, FIG. 9 illustrates that an IC die 142-1 may include the ICs 132-1 and 132-2 of the first layer 134-1 (similar to the implementation of the first layer 134-1 shown in FIG. 8), while the ICs 132-3, 132-4, and 132-5 of the second layer 134-2 may be included in respectively, individual IC dies 142-2, 142-3, and 142-4 (similar to the implementation of the second layer 134-2 shown in FIG. 6). FIG. 10 illustrates that ICs 132-1 and 132-2 of the first layer 134-1 may be included in respectively, individual IC dies 142-1 and 142-2 (similar to the implementation of the first layer 134-1 shown in FIG. 6), while an IC die 142-3 may include the ICs 132-3, 132-4, and 132-5 of the second layer 134-2 (similar to the implementation of the second layer 134-2 shown in FIG. 8). Further embodiments of how the ICs 132 of two or more layers 134 may be distributed over respective IC dies 142 are possible, all of which being within the scope of the present disclosure. In general, any of the layers 134 may include one or more IC dies 142 over which one or more ICs 132 of that layer 134 may be provided, where different ones of the IC dies 142 may include same or different numbers of the ICs 132.

While FIGS. 6-10 illustrate that the width 133 of different ICs 132 is substantially the same, this may be different in other embodiments of the antenna module 100. This is depicted in FIG. 11 illustrating that one or more ICs 132 may be smaller than at least one other IC 132 (e.g., the IC 132-2 is smaller than the IC 132-1 in the dimension measured along the y-axis of the example coordinate system shown) and/or one or more ICs 132 may be larger than at least one other IC 132 (e.g., the IC 132-3 is larger than the IC 132-1 in the dimension measured along the y-axis of the example coordinate system shown). While FIG. 11 illustrates each IC 132 provided on a respective IC die 142, the size of which may be correspondingly modified to fit the respective ICs 132, in other embodiments, the ICs 132 of different sizes may be provided on any arrangement of dies in line with the principles described above (e.g., described with reference to FIGS. 8-10). While the areas between the ICs 132 are shown as empty in FIGS. 6-11, these areas may include an insulator material, such as various semiconductor oxides, organic materials such as epoxies, a mold material, an underfill material, etc.

Arranging the ICs 132 in two different layers 134 allows providing overlapping ICs 132 for a linear array of antenna units 104 (i.e., where the antenna units 104 are arranged along a line, e.g., along a straight line, a curved line, or arranged in a piecewise linear manner), as is illustrated in the top-down view shown in FIG. 7. If a two-dimensional array of antenna units 104 is to be implemented with ICs 132 having average dimensions (e.g., widths) along the axis on which the antenna units 104 are arranged being larger than the pitch of the antenna units 104, then additional layers 134 need to be implemented. FIG. 12 is a top-down view of yet another example of an antenna module 100, in accordance with an embodiment, where the ICs 132 are arranged in four layers 134, to enable a 5×5 array of the antenna units 104. Similar to the top-down view of FIG. 7, FIG. 12 depicts ICs 132 of different layers 134 using different patterns and/or colors, with some layers 134 overlayed over other layers 134 and depicting antenna units 104 as an overlay over all of the ICs 132 (as in FIG. 7). Because it is difficult to illustrate the IC arrangement 130 with four layers 134 with only a top-down view, FIGS. 13A-13D show top-down views of different layers of the antenna module 100 of FIG. 12, in accordance with an embodiment. FIG. 12 and FIGS. 13A-13D provide scaled versions of portions of the antenna module 100 compared to that shown in FIGS. 6-11, in order to fit all of the illustrations of FIGS. 13A-13D on a single page of drawings (and FIG. 12 then matches the same scale but show the layers 134 of FIGS. 13A-13D overlayed over one another).

In order to provide a 5×5 array of the antenna units 104 with the same number of ICs 132, a total of 25 ICs 132 should be included in the IC arrangement 130, distributed between four different layers 134. FIG. 13A illustrates arrangement of ICs 132 of a first layer 134-1, FIG. 13B illustrates arrangement of ICs 132 of a second layer 134-2, FIG. 13C illustrates arrangement of ICs 132 of a third layer 134-3, and FIG. 13D illustrates arrangement of ICs 132 of a fourth layer 134-4.

As shown in FIG. 13A, the first layer 134-1 may include ICs 132-1 and 132-2 in the first row (i.e., a row along a first line parallel to the direction of the y-axis), ICs 132-6 and 132-7 in the second row (i.e., a row along a second line parallel to the direction of the y-axis, the second line being parallel to and separated from the first line), and ICs 132-8 and 132-9 in the third row (i.e., a row along a third line parallel to the direction of the y-axis, the third line being parallel to and separated from each of the first line and the second line). The ICs 132-1 and 132-2 of the first row of the first layer 134-1 may be arranged as the ICs 132-1 and 132-2 of the antenna module 100 described with reference to FIGS. 6-11, and the ICs 132 of other rows of the first layer 134-1 may be arranged similar to the ICs 132 of the first row of the first layer 134-1. For example, ICs 132 of each individual row of the first layer 134-1 may be provided at a pitch 144 as described above (e.g., may be about twice the pitch 140 of the five antenna units 104 provided along that row in the antenna module 100, as shown in FIG. 12). Similarly, ICs 132 of each individual column of the first layer 134-1 may be provided at a pitch 146, which may be about twice a pitch 148 of the five antenna units 104 provided along that column in the antenna module 100, as shown in FIG. 12. In some embodiments, the pitch 146 may be substantially equal to the pitch 144, and the pitch 148 may be substantially equal to the pitch 140, but that may be different in other embodiments.

As shown in FIG. 13B, the second layer 134-2 may include ICs 132-3, 132-4, and 132-5 in the first row (i.e., a row along a first line parallel to the direction of the y-axis), ICs 132-10, 132-11, and 132-12 in the second row (i.e., a row along a second line parallel to the direction of the y-axis, the second line being parallel to and separated from the first line), and ICs 132-13, 132-14, and 132-15 in the third row (i.e., a row along a third line parallel to the direction of the y-axis, the third line being parallel to and separated from each of the first line and the second line). The ICs 132-3, 132-4, and 132-5 of the first row of the second layer 134-2 may be arranged as the ICs 132-3, 132-4, and 132-5 of the antenna module 100 described with reference to FIGS. 6-11, and the ICs 132 of other rows of the second layer 134-2 may be arranged similar to the ICs 132 of the first row of the second layer 134-2. For example, ICs 132 of each individual row of the second layer 134-2 may be provided at a pitch 144 as described above (e.g., may be about twice the pitch 140 of the five antenna units 104 provided along that row in the antenna module 100). Similarly, ICs 132 of each individual column of the second layer 134-2 may be provided at a pitch 146, which may be about twice a pitch 148 of the five antenna units 104 provided along that column in the antenna module 100. Individual rows of the ICs 132 of the second layer 134-2 may be aligned along the x-axis with the individual rows of the ICs 132 of the first layer 134-1. Individual columns of the ICs 132 of the second layer 134-2 may be offset along the y-axis with the individual columns of the ICs 132 of the first layer 134-1 because the ICs 132 of the first layer 134-1 overlap the ICs 132 of the second layer 134-2 along the y-axis (e.g., as shown in FIG. 6 and described above).

As shown in FIG. 13C, the third layer 134-3 may include ICs 132-16, 132-17, and 132-18 in the first row (i.e., a row along a first line parallel to the direction of the y-axis), and ICs 132-19, 132-20, and 132-21 in the second row (i.e., a row along a second line parallel to the direction of the y-axis, the second line being parallel to and separated from the first line). The ICs 132-16, 132-17, and 132-18 of the first row of the third layer 134-3 may be arranged as the ICs 132-3, 132-4, and 132-5 of the antenna module 100 described with reference to FIGS. 6-11, and the ICs 132 of other rows of the third layer 134-3 may be arranged similar to the ICs 132 of the first row of the third layer 134-3. For example, ICs 132 of each individual row of the third layer 134-3 may be provided at a pitch 144 as described above (e.g., may be about twice the pitch 140 of the five antenna units 104 provided along that row in the antenna module 100). Similarly, ICs 132 of each individual column of the third layer 134-3 may be provided at a pitch 146, which may be about twice a pitch 148 of the five antenna units 104 provided along that column in the antenna module 100. Individual columns of the ICs 132 of the third layer 134-3 may be aligned along the y-axis with the individual columns of the ICs 132 of the second layer 134-2. Individual rows of the ICs 132 of the third layer 134-3 may be offset along the x-axis with the individual rows of the ICs 132 of the second layer 134-2 because the ICs 132 of the third layer 134-3 overlap the ICs 132 of the second layer 134-2 along the x-axis (e.g., similar to how it is shown in FIG. 6 and described above, but if the y-axis of FIG. 6 was switched to be an x-axis). Because individual rows of the ICs 132 of the second layer 134-2 may be aligned along the x-axis with the individual rows of the ICs 132 of the first layer 134-1, this means that, if individual rows of the ICs 132 of the third layer 134-3 may be offset along the x-axis with the individual columns of the ICs 132 of the second layer 134-2, then the individual rows of the ICs 132 of the third layer 134-3 are also offset along the x-axis with the individual rows of the ICs 132 of the first layer 134-1.

As shown in FIG. 13D, the fourth layer 134-4 may include ICs 132-22 and 132-23 in the first row (i.e., a row along a first line parallel to the direction of the y-axis), and ICs 132-24 and 132-25 in the second row (i.e., a row along a second line parallel to the direction of the y-axis, the second line being parallel to and separated from the first line). The ICs 132-22 and 132-23 of the first row of the fourth layer 134-4 may be arranged as the ICs 132-1 and 132-2 of the antenna module 100 described with reference to FIGS. 6-11, and the ICs 132 of other rows of the fourth layer 134-4 may be arranged similar to the ICs 132 of the first row of the fourth layer 134-4. For example, ICs 132 of each individual row of the fourth layer 134-4 may be provided at a pitch 144 as described above (e.g., may be about twice the pitch 140 of the five antenna units 104 provided along that row in the antenna module 100). Similarly, ICs 132 of each individual column of the fourth layer 134-4 may be provided at a pitch 146, which may be about twice a pitch 148 of the five antenna units 104 provided along that column in the antenna module 100. Individual rows of the ICs 132 of the fourth layer 134-4 may be aligned along the x-axis with the individual rows of the ICs 132 of the third layer 134-3. Individual columns of the ICs 132 of the fourth layer 134-4 may be aligned along the y-axis with the individual columns of the ICs 132 of the first layer 134-1. Similar to the third layer 134-3, individual rows of the ICs 132 of the fourth layer 134-4 may be offset along the x-axis with the individual rows of the ICs 132 of the second layer 134-2 because the ICs 132 of the fourth layer 134-4 overlap the ICs 132 of the second layer 134-2 along the x-axis (e.g., similar to how it is shown in FIG. 6 and described above, but if the y-axis of FIG. 6 was switched to be an x-axis). Because individual rows of the ICs 132 of the second layer 134-2 may be aligned along the x-axis with the individual rows of the ICs 132 of the first layer 134-1, this means that, if individual rows of the ICs 132 of the fourth layer 134-4 may be offset along the x-axis with the individual rows of the ICs 132 of the second layer 134-2, then the individual rows of the ICs 132 of the fourth layer 134-4 are also offset along the x-axis with the individual rows of the ICs 132 of the first layer 134-1. Individual columns of the ICs 132 of the fourth layer 134-4 may be offset along the y-axis with the individual columns of the ICs 132 of the second layer 134-2 because the ICs 132 of the fourth layer 134-4 overlap the ICs 132 of the second layer 134-2 along the y-axis (e.g., similar to how it is shown in FIG. 6 and described above). Because individual columns of the ICs 132 of the second layer 134-2 may be aligned along the y-axis with the individual columns of the ICs 132 of the third layer 134-3, this means that, if individual columns of the ICs 132 of the fourth layer 134-4 may be offset along the y-axis with the individual columns of the ICs 132 of the second layer 134-2, then the individual columns of the ICs 132 of the fourth layer 134-4 are also offset along the y-axis with the individual columns of the ICs 132 of the third layer 134-3.

In various embodiments, the vertical order (i.e., order along the z-axis of the example coordinate system shown) of the layers 134-1, 134-2, 134-3, and 134-4 of the antenna module 100 as shown in FIGS. 12-13 may be different. For the IC arrangement 130 as shown in FIG. 12, the vertical order of the layers 134 may be as follows. The layer 134-2 may be between the layers 134-1 and 134-3, where one of the layers 134-1 and 134-3 may be on top and the other one of the layers 134-1 and 134-3 may be at the bottom, but which one is on top and which one is at the top may be different in different embodiments. The layer 134-4 may be either at the top of all other layers or at the bottom of all the other layers. Thus, in a first embodiment of the antenna module 100 as shown in FIGS. 12-13, the vertical order of the layers 134, starting from the layer closest to the antenna support unit 110, may be as follows: the first layer 134-1, the second layer 134-2, the third layer 134-3, and the fourth layer 134-4. In a second embodiment of the antenna module 100 as shown in FIGS. 12-13, the vertical order of the layers 134, starting from the layer closest to the antenna support unit 110, may be as follows: the third layer 134-3, the second layer 134-2, the first layer 134-1, and the fourth layer 134-4. In a third embodiment of the antenna module 100 as shown in FIGS. 12-13, the vertical order of the layers 134, starting from the layer closest to the antenna support unit 110, may be as follows: the fourth layer 134-4, the first layer 134-1, the second layer 134-2, and the third layer 134-3. In a fourth embodiment of the antenna module 100 as shown in FIGS. 12-13, the vertical order of the layers 134, starting from the layer closest to the antenna support unit 110, may be as follows: the fourth layer 134-4, the third layer 134-3, the second layer 134-2, and the first layer 134-1.

For the antenna module 100 as shown in FIGS. 12-13, if looking from the perspective of a given row of the antenna units 104 or of a given column of the antenna units 104, an average pitch of projections of all of the ICs 132 along that row/column onto a plane parallel to the antenna unit support 110 may be substantially equal to, or smaller, than an average pitch of the antenna units 104 along that row/column. For example, for a column 152-1 of the antenna units 104 shown in the top-down view of FIG. 12, an average pitch of projections of all of the ICs 132 along the column 152-1 (i.e., ICs 132-3, 132-10, and 132-14 of the second layer 134-2 and ICs 132-16 and 132-19 of the third layer 134-3) onto a plane parallel to the antenna unit support 110 may be substantially equal to an average pitch of the antenna units 104 along the column 152-1. For a column 152-2 of the antenna units 104 shown in the top-down view of FIG. 12, an average pitch of projections of all of the ICs 132 along the column 152-2 (i.e., ICs 132-1, 132-6, and 132-8 of the first layer 134-1 and ICs 132-22 and 132-24 of the fourth layer 134-4) onto a plane parallel to the antenna unit support 110 may be substantially equal to an average pitch of the antenna units 104 along the column 152-2. For a column 152-3 of the antenna units 104 shown in the top-down view of FIG. 12, an average pitch of projections of all of the ICs 132 along the column 152-3 (i.e., ICs 132-4, 132-11, and 132-14 of the second layer 134-2 and ICs 132-17 and 132-20 of the third layer 134-3) onto a plane parallel to the antenna unit support 110 may be substantially equal to an average pitch of the antenna units 104 along the column 152-3. For a column 152-4 of the antenna units 104 shown in the top-down view of FIG. 12, an average pitch of projections of all of the ICs 132 along the column 152-4 (i.e., ICs 132-2, 132-7, and 132-9 of the first layer 134-1 and ICs 132-23 and 132-25 of the fourth layer 134-4) onto a plane parallel to the antenna unit support 110 may be substantially equal to an average pitch of the antenna units 104 along the column 152-4. For a column 152-5 of the antenna units 104 shown in the top-down view of FIG. 12, an average pitch of projections of all of the ICs 132 along the column 152-5 (i.e., ICs 132-5, 132-12, and 132-15 of the second layer 134-2 and ICs 132-18 and 132-21 of the third layer 134-3) onto a plane parallel to the antenna unit support 110 may be substantially equal to an average pitch of the antenna units 104 along the column 152-5. Analogous applies to rows 154 of the antenna units 104 shown in the top-down view of FIG. 12. For example, for a row 154-1 of the antenna units 104 shown in the top-down view of FIG. 12, an average pitch of projections of all of the ICs 132 along the row 154-1 (i.e., ICs 132-1 and 132-2 of the first layer 134-1 and ICs 132-3, 132-4, and 132-5 of the second layer 134-2) onto a plane parallel to the antenna unit support 110 may be substantially equal to an average pitch of the antenna units 104 along the row 154-1 (this is similar to the embodiments of linear arrays of the antenna units 104 as shown in FIGS. 6-11). For a row 154-2 of the antenna units 104 shown in the top-down view of FIG. 12, an average pitch of projections of all of the ICs 132 along the row 154-2 (i.e., ICs 132-16, 132-17, and 132-18 of the third layer 134-3 and ICs 132-22 and 132-23 of the fourth layer 134-4) onto a plane parallel to the antenna unit support 110 may be substantially equal to an average pitch of the antenna units 104 along the row 154-2. For a row 154-3 of the antenna units 104 shown in the top-down view of FIG. 12, an average pitch of projections of all of the ICs 132 along the row 154-3 (i.e., ICs 132-6 and 132-7 of the first layer 134-1 and ICs 132-10, 132-11, and 132-12 of the second layer 134-2) onto a plane parallel to the antenna unit support 110 may be substantially equal to an average pitch of the antenna units 104 along the row 154-3. For a row 154-4 of the antenna units 104 shown in the top-down view of FIG. 12, an average pitch of projections of all of the ICs 132 along the row 154-4 (i.e., ICs 132-19, 132-20, and 132-21 of the third layer 134-3 and ICs 132-24 and 132-25 of the fourth layer 134-4) onto a plane parallel to the antenna unit support 110 may be substantially equal to an average pitch of the antenna units 104 along the row 154-4. For a row 154-5 of the antenna units 104 shown in the top-down view of FIG. 12, an average pitch of projections of all of the ICs 132 along the row 154-5 (i.e., ICs 132-8 and 132-9 of the first layer 134-1 and ICs 132-13, 132-14, and 132-15 of the second layer 134-2) onto a plane parallel to the antenna unit support 110 may be substantially equal to an average pitch of the antenna units 104 along the row 154-5. It should be noted that not all ICs 132 are individually labeled in the view of FIG. 12 in order to not clutter the drawing. It should also be noted that the example of a two-dimensional arrangement of the antenna units 104 and their respective ICs 132 at four different layers 134 is just one example and further embodiments along the lines of the descriptions provided herein are possible and within the scope of the present disclosure.

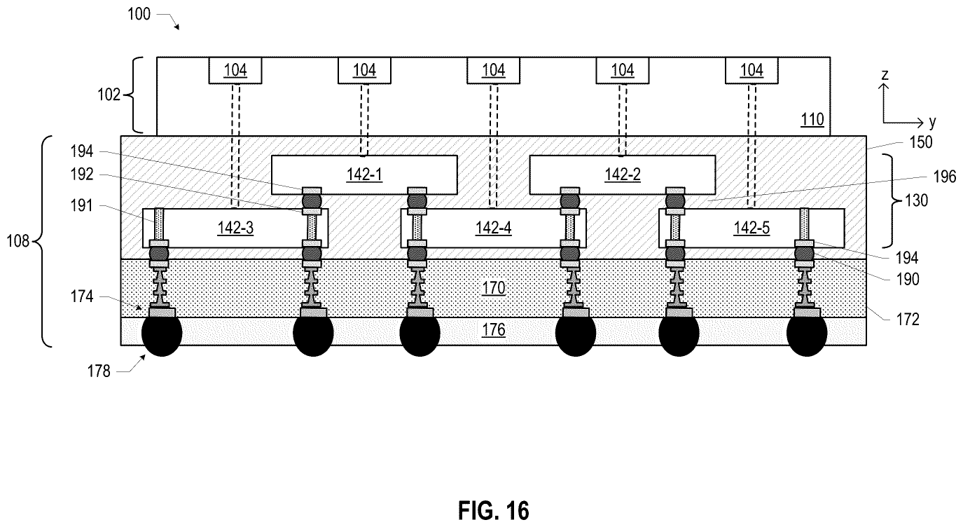

While FIGS. 6-13 were focusing on illustrating details of different IC arrangements 130 of an antenna module 100 in accordance with various embodiments, FIGS. 14-16 are side, cross-sectional views illustrating details of different example IC packages 108 of an antenna module 100, in accordance with various embodiments. Each of FIGS. 14-16 illustrates an IC arrangement 130 of IC dies 142-1 through 142-5 as described with reference to FIGS. 6-7 (individual ICs 132 within each of the IC dies 142-1 through 142-5 are not shown in FIGS. 14-16 in order to not clutter the drawings), but descriptions provided with respect to FIGS. 14-16 are equally applicable to IC arrangements 130 as shown in FIGS. 8-13, with some straightforward modifications that would be apparent in view of the descriptions of FIGS. 6-13. Thus, in general, any of the IC arrangements 130 described with reference to one or more of FIGS. 6-13 may be combined with the remaining details of the IC packages 108 described with reference to one or more of FIGS. 14-16 to build an antenna module 100.

The remainder of the IC package 108 (i.e., besides the IC arrangement 130 as described with reference to FIGS. 6-13) included in an antenna module 100 may have any suitable structure. For example, FIG. 14 illustrates an example IC package that may include a base die 160 coupled to one or more of the IC dies 142 housing the ICs 132 of the IC arrangement 130, and a package substrate 170 coupled to the base die 160.

The base die 160 may include any suitable IC components. In some embodiments, the base die 160 may include digital circuitry of an RF device (e.g., of the RF device 2500 of FIG. 23). For example, in some embodiments, the base die 160 may include a digital processing unit 2508 and/or a local oscillator 2506 of the RF device 2500 (FIG. 23). In some embodiments, the base die 160 may include a memory device programmed with instructions to execute beam forming, scanning, and/or codebook functions. In various embodiments, the base die 160 may include a resistor, capacitor (e.g., decoupling capacitors), inductor, DC-DC converter circuitry, voltage regulators, or other circuit elements.

In some embodiments, the base die 160 may be coupled to the package substrate 170 by first-level interconnects 180. In particular, conductive contacts 172 at one face of the package substrate 170 may be coupled to conductive contacts 164 at one face of the base die 160 by first-level interconnects 180. The first-level interconnects 180 illustrated in FIG. 14 are solder bumps, but any suitable first-level interconnects 180 may be used. A solder resist 176 may be disposed around the conductive contacts 172. Although not specifically shown, an underfill material may also be present, e.g., disposed around some portions of the conductive contacts 172. The package substrate 170 may include a dielectric material, and may have conductive pathways 171 (e.g., including conductive vias and lines) extending through the dielectric material between the faces of the package substrate 170, or between different locations on each face of the package substrate 170. In some embodiments, the package substrate 170 may have a thickness less than 1 millimeter (e.g., between 0.1 millimeters and 0.5 millimeters). Conductive contacts 174 may be disposed at the other face of the package substrate 170, and second-level interconnects 178 may couple these conductive contacts 174 to a further component (not shown), such as a circuit board or an interposer, in an antenna module 100. The second-level interconnects 178 illustrated in FIG. 14 are solder balls (e.g., for a ball grid array arrangement), but any suitable second-level interconnects 178 may be used (e.g., pins in a pin grid array arrangement or lands in a land grid array arrangement). A solder resist 176 may be disposed around the conductive contacts 174.

In some embodiments, the base die 160 may be coupled to any of the IC dies 142 by interconnects 190. In particular, conductive contacts 194 at the bottom face of the IC dies 142 may be coupled to conductive contacts 162 at the top face of the base die 160 by the interconnects 190. The interconnects 190 may be solder bumps, hybrid bonding interconnects, direct bonding interconnects, or any other suitable first-level interconnects. In some embodiments, some IC dies 142 may not be directly connected to the base die 160, but may be connected to the base die 160 via other IC dies 142. For example, FIG. 14 illustrates that the IC dies 142 of the layer 134 that is farthest away from the antenna support unit 110 may be directly connected to the base die 160 via the interconnects 190, while the IC dies 142 of the layer 134 above the layer 134 that is farthest away from the antenna support unit 110 may be connected to the base die 160 via the interconnects 196 between the IC dies 142 of these two layers 134. In particular, conductive contacts 194 at the bottom face of the IC dies 142 of the first layer 134-1 may be coupled to conductive contacts 192 at the top face of the IC dies 142 of the second layer 134-2 by the interconnects 196. The interconnects 196 may be solder bumps, hybrid bonding interconnects, direct bonding interconnects, or any other suitable first-level interconnects. Any of the IC dies 142 may have conductive pathways 191 (e.g., including conductive vias and lines) extending through the dielectric material between the faces of an IC die 142, or between different locations on each face of an IC die 142.

In some embodiments, a mold material 150 may be disposed around the IC dies 142 (e.g., between the IC dies 142 and the base die 160 as an underfill material). Example materials that may be used for the mold material 150 include epoxy mold materials, inorganic materials such as semiconductor oxides, etc., as suitable. In other embodiments, a mold material 150 may be absent.

FIG. 15 illustrates an antenna module 100 with an example IC package 108 that also includes a base die 160 and a package substrate 170, as described with reference to FIG. 14, but, in the embodiment of FIG. 15, the package substrate 170 is between the base die 160 and the one or more of the IC dies 142 housing the ICs 132 of the IC arrangement 130. In such an embodiment, the base die 160 may still be coupled to the package substrate 170 by first-level interconnects 180 as described above but in a way where the first-level interconnects 180 couple conductive contacts 174 at one face of the package substrate 170 to conductive contacts 162 at one face of the base die 160. A solder resist 176 may be disposed around the conductive contacts 174. Although not specifically shown, an underfill material may also be present, e.g., disposed around some portions of the conductive contacts 176. Conductive contacts 164 may be disposed at the other face of the base die 160, and second-level interconnects 178 as described above may couple these conductive contacts 164 to a further component (not shown), such as a circuit board or an interposer, in an antenna module 100. A solder resist 176 may be disposed around the conductive contacts 164. Furthermore, in the embodiment of FIG. 15, the package substrate 170 may be coupled to any of the IC dies 142 by interconnects 190 as described above. In particular, conductive contacts 194 at the bottom face of the IC dies 142 may be coupled to conductive contacts 172 at the top face of the package substrate 170 by the interconnects 190. In some embodiments, some IC dies 142 may not be directly connected to the package substrate 170, but may be connected to the package substrate 170 via other IC dies 142. For example, FIG. 14 illustrates that the IC dies 142 of the layer 134 that is farthest away from the antenna support unit 110 may be directly connected to the package substrate 170 via the interconnects 190, while the IC dies 142 of the layer 134 above the layer 134 that is farthest away from the antenna support unit 110 may be connected to the package substrate 170 via the interconnects 196 between the IC dies 142 of these two layers 134.

FIG. 16 illustrates an antenna module 100 with an example IC package 108 that includes a package substrate 170 as described with reference to FIG. 15, but does not include a base die 160. In such an embodiment, the conductive contacts 174 at one face of the package substrate 170 and second-level interconnects 178 as described above may couple the package substrate 170 to a further component (not shown), such as a circuit board or an interposer, in an antenna module 100. A solder resist 176 may be disposed around the conductive contacts 174.

Various arrangements of the IC packages 108 as shown in FIGS. 14-16 do not represent an exhaustive set of IC packages in which IC arrangements 130 with partially overlapping stacked ICs 132 as described herein may be implemented, but merely provide examples of such IC packages. In particular, the number and positions of various elements shown in FIGS. 14-16 is purely illustrative and, in various other embodiments, other numbers of these elements, provided in other locations relative to one another may be used in accordance with the general architecture considerations described herein. For example, although not specifically shown in the present drawings, in some embodiments, an IC package 108 may include a redistribution layer (RDL) between any pair of layers 134 of the IC arrangements 130 or between any other components of the IC package 108, the RDL including a plurality of interconnect structures (e.g., conductive lines and conductive vias) to assist routing of signals and/or power between components. In another example, although also not specifically shown in the present drawings, in some embodiments, a package substrate 170 of an IC package 108 may include one or more recesses. In such embodiments, a bottom surface of a recess in the package substrate 170 may be provided by solid material of the package substrate 170. A recess may be formed in a package substrate 170 in any suitable manner (e.g., via three-dimensional printing, etching, laser cutting or drilling the recess into an existing package substrate, etc.). One or more ICs 132 or other IC components of the antenna module 100 may be positioned over or at least partially in such a recess.

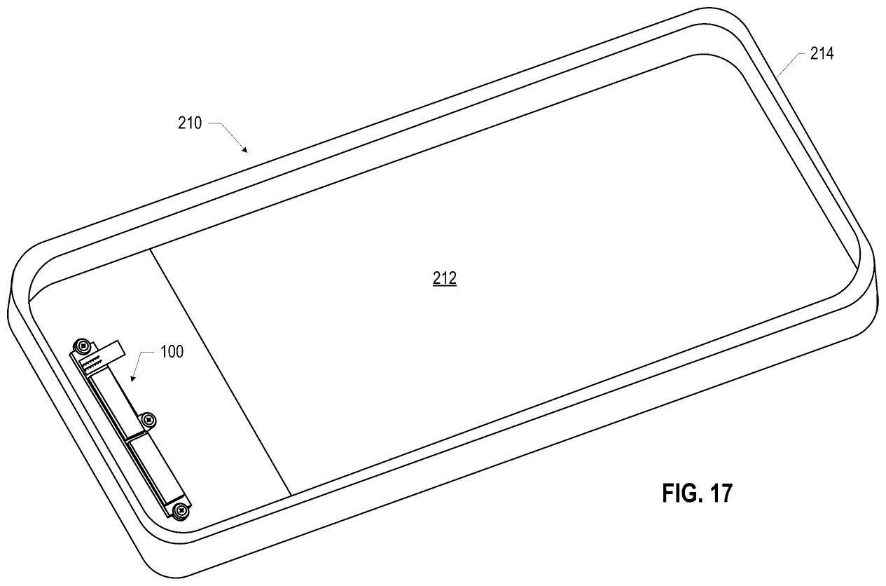

Antenna modules 100 and/or IC packages 108 disclosed herein may be included in any suitable communication device (e.g., a computing device with wireless communication capability, a wearable device with wireless communication circuitry, etc.). For example, FIG. 17 is a perspective view of a handheld communication device 210 including an antenna module 100 having an IC package 108 with one or more IC arrangements 130, in accordance with various embodiments. In particular, FIG. 17 depicts that the antenna module 100 (and associated IC package fixtures) may be coupled to a chassis 212 of the handheld communication device 210. A metal or plastic housing 214 may provide the “sides” of the communication device 210. In some embodiments, the handheld communication device 210 may be a smart phone.

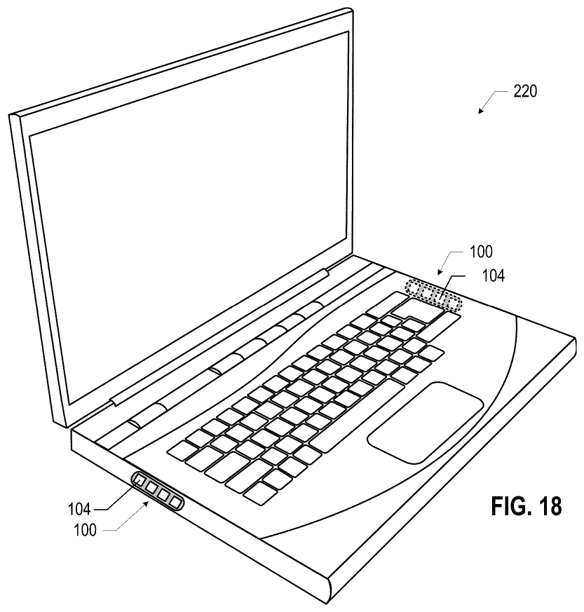

FIG. 18 is a perspective view of a laptop communication device 220 including multiple antenna modules 100, each including one or more IC packages 108 with one or more IC arrangements 130, in accordance with various embodiments. In particular, FIG. 18 depicts an antenna module 100 with four antenna units 104, as an example, at either side of the keyboard of a laptop communication device 220. The stacks 120 may occupy an area on the outside housing of the laptop communication device 220 that is approximately equal to or less than the area required for two adjacent Universal Serial Bus (USB) connectors (i.e., approximately 5 millimeters (height) by 22 millimeters (width) by 2.2 millimeters (depth)).

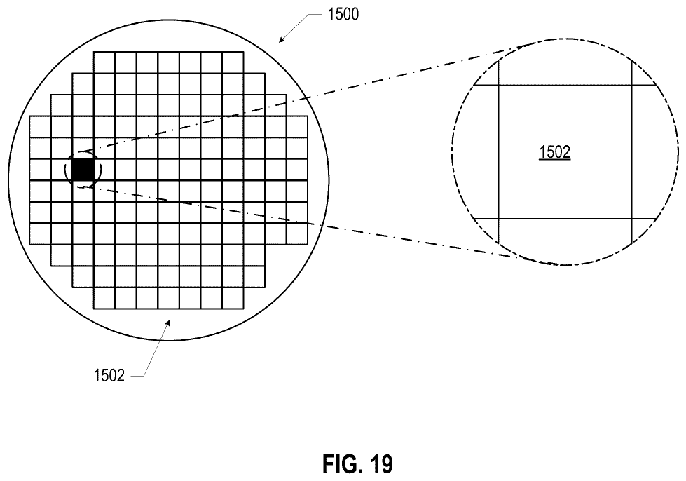

The IC arrangements 130 disclosed herein may include, or be included in, any suitable electronic component. FIGS. 19-23 illustrate various examples of apparatuses that may include, or be included in, any of the IC arrangements 130 disclosed herein, where the IC arrangements 130 may be, e.g., a part of an antenna module 100 and/or an IC package 108 as described herein.

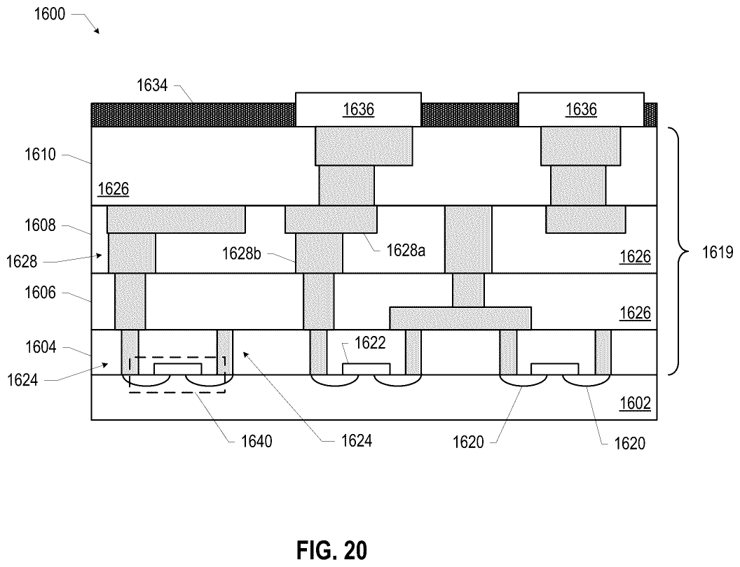

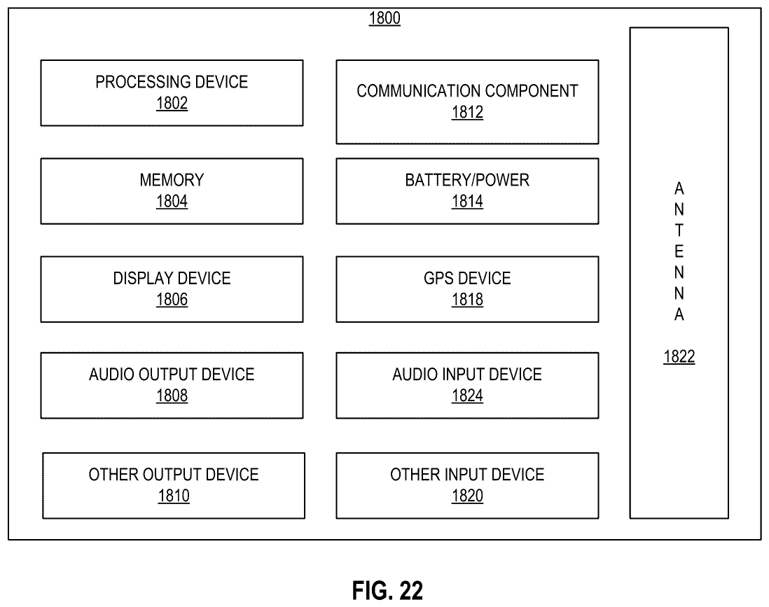

FIG. 19 is a top view of a wafer 1500 and dies 1502 that may be included in any of the IC arrangements 130 as described herein, e.g., as a part of an antenna module 100 and/or an IC package 108 as described herein. For example, a die 1502 may be any of the IC dies 142 described herein and/or may include one or more ICs 132 of an IC arrangement 130 described herein. The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may include one or more transistors (e.g., some of the transistors 1640 of FIG. 20, discussed below) and/or supporting circuitry to route electrical signals to the transistors, as well as any other IC components. In some embodiments, the wafer 1500 or the die 1502 may include a memory device (e.g., a random-access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 22) or other logic that is configured to store information in the memory devices or execute instructions stored in the memory array.

FIG. 20 is a side, cross-sectional view of an IC device 1600 that may be included in any of the IC arrangements 130 as described herein, e.g., as a part of an antenna module 100 and/or an IC package 108 as described herein. For example, an IC device 1600 may include one or more ICs 132 of an IC arrangement 130 described herein. The IC device 1600 may be formed on a substrate 1602 (e.g., the wafer 1500 of FIG. 19) and may be included in a die (e.g., the die 1502 of FIG. 19). The substrate 1602 may be a semiconductor substrate composed of semiconductor material systems including, for example, n-type or p-type materials systems (or a combination of both). The substrate 1602 may include, for example, a crystalline substrate formed using a bulk silicon or a silicon-on-insulator (SOI) substructure. In some embodiments, the substrate 1602 may be formed using alternative materials, which may or may not be combined with silicon, that include but are not limited to germanium, indium antimonide, lead telluride, indium arsenide, indium phosphide, gallium arsenide, or gallium antimonide. Further materials classified as group III-V materials (i.e., materials from groups III and V of the periodic system of elements), group II-VI (i.e., materials from groups II and IV of the periodic system of elements), or group IV materials (i.e., materials from group IV of the periodic system of elements) may also be used to form the substrate 1602. Although a few examples of materials from which the substrate 1602 may be formed are described here, any material that may serve as a foundation for an IC device 1600 may be used. The substrate 1602 may be part of a singulated die (e.g., the dies 1502 of FIG. 19) or a wafer (e.g., the wafer 1500 of FIG. 19).

The IC device 1600 may include one or more device layers 1604 disposed on the substrate 1602. The device layer 1604 may include features of one or more transistors 1640 (e.g., metal oxide semiconductor field-effect transistors (MOSFETs)) formed on the substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 20 and may include a wide variety of other types and configurations such as, for example, planar transistors, non-planar transistors, or a combination of both. Planar transistors may include bipolar junction transistors (BJT), heterojunction bipolar transistors (HBT), or high-electron-mobility transistors (HEMT). Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1640 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1640 along the source-channel-drain direction, the gate electrode may consist of a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1620 may be formed within the substrate 1602 adjacent to the gate 1622 of each transistor 1640. The S/D regions 1620 may be formed using an implantation/diffusion process or an etching/deposition process, for example. In the former process, dopants such as boron, aluminum, antimony, phosphorous, or arsenic may be ion-implanted into the substrate 1602 to form the S/D regions 1620. An annealing process that activates the dopants and causes them to diffuse farther into the substrate 1602 may follow the ion-implantation process. In the latter process, the substrate 1602 may first be etched to form recesses at the locations of the S/D regions 1620. An epitaxial deposition process may then be carried out to fill the recesses with material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620.

Electrical signals, such as power and/or input/output (I/O) signals, may be routed to and/or from the devices (e.g., the transistors 1640) of the device layer 1604 through one or more interconnect layers disposed on the device layer 1604 (illustrated in FIG. 20 as interconnect layers 1606, 1608, and 1610). For example, electrically conductive features of the device layer 1604 (e.g., the gate 1622 and the S/D contacts 1624) may be electrically coupled with the interconnect structures 1628 of the interconnect layers 1606, 1608, and 1610. The one or more interconnect layers 1606, 1608, and 1610 may form a metallization stack (also referred to as an “ILD stack”) 1619 of the IC device 1600.

The interconnect structures 1628 may be arranged within the interconnect layers 1606-1610 to route electrical signals according to a wide variety of designs (in particular, the arrangement is not limited to the particular configuration of interconnect structures 1628 depicted in FIG. 20). Although a particular number of interconnect layers 1606, 1608, and 1610 is depicted in FIG. 20, embodiments of the present disclosure include IC devices having more or fewer interconnect layers than depicted.

In some embodiments, the interconnect structures 1628 may include lines 1628a and/or vias 1628b filled with an electrically conductive material such as a metal. The lines 1628a may be arranged to route electrical signals in a direction of a plane that is substantially parallel with a surface of the substrate 1602 upon which the device layer 1604 is formed. For example, the lines 1628a may route electrical signals in a direction in and out of the page from the perspective of FIG. 20. The vias 1628b may be arranged to route electrical signals in a direction of a plane that is substantially perpendicular to the surface of the substrate 1602 upon which the device layer 1604 is formed. In some embodiments, the vias 1628b may electrically couple lines 1628a of different interconnect layers 1606, 1608, and 1610 together.

The interconnect layers 1606, 1608, and 1610 may include a dielectric material 1626 disposed between the interconnect structures 1628, as shown in FIG. 20. In some embodiments, the dielectric material 1626 disposed between the interconnect structures 1628 in different ones of the interconnect layers 1606, 1608, and 1610 may have different compositions; in other embodiments, the composition of the dielectric material 1626 between different interconnect layers 1606, 1608, and 1610 may be the same.

A first interconnect layer 1606 may be formed above the device layer 1604. In some embodiments, the first interconnect layer 1606 may include lines 1628a and/or vias 1628b, as shown. The lines 1628a of the first interconnect layer 1606 may be coupled with contacts (e.g., the S/D contacts 1624) of the device layer 1604.

A second interconnect layer 1608 may be formed above the first interconnect layer 1606. In some embodiments, the second interconnect layer 1608 may include vias 1628b to couple the lines 1628a of the second interconnect layer 1608 with the lines 1628a of the first interconnect layer 1606. Although the lines 1628a and the vias 1628b are structurally delineated with a line within each interconnect layer (e.g., within the second interconnect layer 1608) for the sake of clarity, the lines 1628a and the vias 1628b may be structurally and/or materially contiguous (e.g., simultaneously filled during a dual-damascene process) in some embodiments.

A third interconnect layer 1610 (and additional interconnect layers, as desired) may be formed in succession on the second interconnect layer 1608 according to similar techniques and configurations described in connection with the second interconnect layer 1608 or the first interconnect layer 1606. In some embodiments, the interconnect layers that are “higher up” in the metallization stack 1619 in the IC device 1600 (i.e., farther away from the device layer 1604) may be thicker.

The IC device 1600 may include a solder resist material 1634 (e.g., polyimide or similar material) and one or more conductive contacts 1636 formed on the interconnect layers 1606, 1608, and 1610. In FIG. 20, the conductive contacts 1636 are illustrated as taking the form of bond pads. The conductive contacts 1636 may be electrically coupled with the interconnect structures 1628 and configured to route the electrical signals of the transistor(s) 1640 to other external devices. For example, solder bonds may be formed on the one or more conductive contacts 1636 to mechanically and/or electrically couple a chip including the IC device 1600 with another component (e.g., a circuit board). The IC device 1600 may include additional or alternate structures to route the electrical signals from the interconnect layers 1606, 1608, and 1610; for example, the conductive contacts 1636 may include other analogous features (e.g., posts) that route the electrical signals to external components.

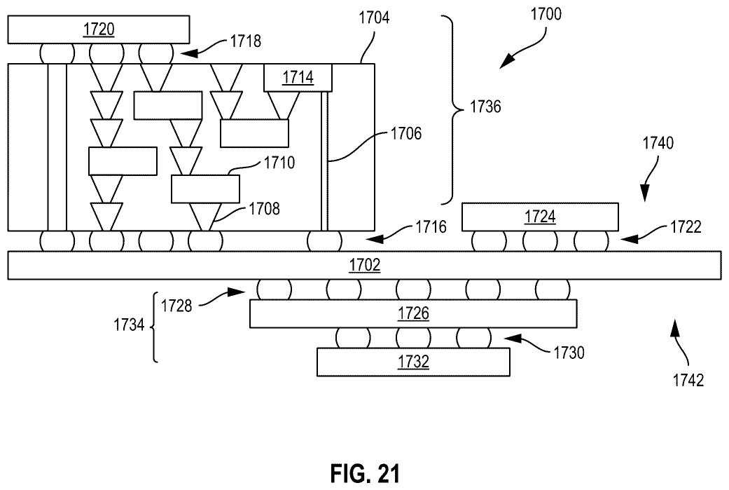

FIG. 21 is a side, cross-sectional view of an IC device assembly 1700 that may include one or more of the IC arrangements 130 as described herein, e.g., as a part of an antenna module 100 and/or an IC package 108 as described herein. In particular, any suitable ones of the antenna modules 100 and/or IC packages 108 disclosed herein may take the place of any of the components of the IC device assembly 1700 (e.g., an IC package 108 or an antenna module 100 with one or more IC packages 108 may take the place of any of the IC packages of the IC device assembly 1700).

The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742.

In some embodiments, the circuit board 1702 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 21 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 21), male and female portions of a socket, an adhesive, an underfill material, and/or any other suitable electrical and/or mechanical coupling structure.

The package-on-interposer structure 1736 may include an IC package 1720 coupled to an interposer 1704 by coupling components 1718. The coupling components 1718 may take any suitable form for the application, such as the forms discussed above with reference to the coupling components 1716. The IC package 1720 may include one or more IC arrangements 130 as described herein, e.g., as a part of an antenna module 100 and/or an IC package 108 as described herein. Although a single IC package 1720 is shown in FIG. 21, multiple IC packages may be coupled to the interposer 1704; indeed, additional interposers may be coupled to the interposer 1704. The interposer 1704 may provide an intervening substrate used to bridge the circuit board 1702 and the IC package 1720. The IC package 1720 may be or include, for example, a die (the die 1502 of FIG. 19), an IC device (e.g., the IC device 1600 of FIG. 20), or any other suitable component. Generally, the interposer 1704 may spread a connection to a wider pitch or reroute a connection to a different connection. For example, the interposer 1704 may couple the IC package 1720 (e.g., a die) to a set of ball grid array (BGA) conductive contacts of the coupling components 1716 for coupling to the circuit board 1702. In the embodiment illustrated in FIG. 21, the IC package 1720 and the circuit board 1702 are attached to opposing sides of the interposer 1704; in other embodiments, the IC package 1720 and the circuit board 1702 may be attached to a same side of the interposer 1704. In some embodiments, three or more components may be interconnected by way of the interposer 1704.

In some embodiments, the interposer 1704 may be formed as a PCB, including multiple metal layers separated from one another by layers of dielectric material and interconnected by electrically conductive vias. In some embodiments, the interposer 1704 may be formed of an epoxy resin, a fiberglass-reinforced epoxy resin, an epoxy resin with inorganic fillers, a ceramic material, or a polymer material such as polyimide. In some embodiments, the interposer 1704 may be formed of alternate rigid or flexible materials that may include the same materials described above for use in a semiconductor substrate, such as silicon, germanium, and other group III-V and group IV materials. The interposer 1704 may include metal interconnects 1708 and vias 1710, including but not limited to through-silicon vias (TSVs) 1706. The interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as RF devices, PAs, power management devices, antennas, arrays, sensors, and microelectromechanical systems (MEMS) devices may also be formed on the interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 21 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 22 is a block diagram of an example communication device 1800 that may include one or more IC arrangements 130 in accordance with any of the embodiments disclosed herein. The handheld communication device 210 (FIG. 17), and the laptop communication device 220 (FIG. 18) may be examples of the communication device 1800. Any suitable ones of the components of the communication device 1800 may include one or more of the IC packages 108, 1720, 1724, IC device assemblies 1700, IC devices 1600, or dies 1502 disclosed herein. In particular, any suitable ones of the components of the communication device 1800 may include one or more IC arrangements 130 as described herein, e.g., as a part of an antenna module 100 and/or an IC package 108 as described herein. A number of components are illustrated in FIG. 22 as included in the communication device 1800, but any one or more of these components may be omitted or duplicated, as suitable for the application. In some embodiments, some or all of the components included in the communication device 1800 may be attached to one or more motherboards. In some embodiments, some or all of these components are fabricated onto a single system-on-a-chip (SoC) die.

Additionally, in various embodiments, the communication device 1800 may not include one or more of the components illustrated in FIG. 22, but the communication device 1800 may include interface circuitry for coupling to the one or more components. For example, the communication device 1800 may not include a display device 1806, but may include display device interface circuitry (e.g., a connector and driver circuitry) to which a display device 1806 may be coupled. In another set of examples, the communication device 1800 may not include an audio input device 1824 or an audio output device 1808, but may include audio input or output device interface circuitry (e.g., connectors and supporting circuitry) to which an audio input device 1824 or audio output device 1808 may be coupled.

The communication device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The communication device 1800 may include a memory 1804, which may itself include one or more memory devices such as volatile memory (e.g., dynamic RAM (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded DRAM (eDRAM) or spin transfer torque magnetic RAM (STT-MRAM).

In some embodiments, the communication device 1800 may include a communication module 1812 (e.g., one or more communication modules). For example, the communication module 1812 may be configured for managing wireless communications for the transfer of data to and from the communication device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not. The communication module 1812 may be, or may include, any of the antenna modules 100 disclosed herein.

The communication module 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication module 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication module 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication module 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication module 1812 may operate in accordance with other wireless protocols in other embodiments. The communication device 1800 may include an antenna 1822 to facilitate wireless communications and/or to receive other wireless communications (such as AM or FM radio transmissions). The antenna 1822 may include one or more IC arrangements 130 as described herein, e.g., as a part of an antenna module 100 and/or an IC package 108 as described herein.

In some embodiments, the communication module 1812 may manage wired communications, such as electrical, optical, or any other suitable communication protocols (e.g., the Ethernet). As noted above, the communication module 1812 may include multiple communication modules. For instance, a first communication module 1812 may be dedicated to shorter-range wireless communications such as Wi-Fi or Bluetooth, and a second communication module 1812 may be dedicated to longer-range wireless communications such as global positioning system (GPS), EDGE, GPRS, CDMA, WiMAX, LTE, EV-DO, or others. In some embodiments, a first communication module 1812 may be dedicated to wireless communications, and a second communication module 1812 may be dedicated to wired communications. In some embodiments, the communication module 1812 may support millimeter wave communication.

The communication device 1800 may include battery/power circuitry 1814. The battery/power circuitry 1814 may include one or more energy storage devices (e.g., batteries or capacitors) and/or circuitry for coupling components of the communication device 1800 to an energy source separate from the communication device 1800 (e.g., AC line power).

The communication device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The communication device 1800 may include an audio output device 1808 (or corresponding interface circuitry, as discussed above). The audio output device 1808 may include any device that generates an audible indicator, such as speakers, headsets, or earbuds.

The communication device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The communication device 1800 may include a GPS device 1818 (or corresponding interface circuitry, as discussed above). The GPS device 1818 may be in communication with a satellite-based system and may receive a location of the communication device 1800, as known in the art.

The communication device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The communication device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The communication device 1800 may have any desired form factor, such as a handheld or mobile communication device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop communication device, a server or other networked computing component, a printer, a scanner, a monitor, a set-top box, an entertainment control unit, a vehicle control unit, a digital camera, a digital video recorder, or a wearable communication device. In some embodiments, the communication device 1800 may be any other electronic device that processes data.

FIG. 23 is a block diagram of an example RF device 2500 that may include one or more IC arrangements 130 in accordance with any of the embodiments disclosed herein. Any suitable ones of the components of the RF device 2500 may include, or may be included in, one or more IC arrangements 130 as described herein, e.g., as a part of an antenna module 100 and/or an IC package 108 as described herein. For example, an antenna 2502 of the RF device 2500 may include one or more IC arrangements 130 as described herein, e.g., as a part of an antenna module 100 and/or an IC package 108 as described herein. In another example, any of the ICs 132 of the IC arrangements 130 described herein may include an RX path amplifier 2512 and/or a TX path amplifier 2522 of the RF device 2500. Any of the components of the RF device 2500 may include, or be included in, an IC device assembly 1700 as described with reference to FIG. 21. In some embodiments, the RF device 2500 may be included within any components of the computing device 1800 as described above with reference to FIG. 22 (e.g., the communication component 1812), or may be coupled to any of the components of the electrical device 1800 (e.g., may be coupled to the memory 1804 and/or to the processing device 1802 of the electrical device 1800). In still other embodiments, the RF device 2500 may further include any of the components described above with reference to FIG. 22, such as, but not limited to, the battery/power circuitry 1814, the memory 1804, and various input and output devices as discussed above with reference to FIG. 22.

In general, the RF device 2500 may be any device or system that may support wireless transmission and/or reception of signals in the form of electromagnetic waves in the RF range of approximately 3 kiloHertz (kHz) to 300 GHz and beyond. In some embodiments, the RF device 2500 may be used for wireless communications, e.g., in a base station (BS) or a user equipment (UE) device of any suitable cellular wireless communications technology, such as GSM, WCDMA, or LTE. In a further example, the RF device 2500 may be used as, or in, a BS or a UE device of a millimeter wave wireless technology such as fifth generation (5G) wireless (e.g., high-frequency/short wavelength spectrum, with frequencies in the range between about 20 and 60 GHZ, corresponding to wavelengths in the range between about 5 and 15 millimeters). In yet another example, the RF device 2500 may be used for wireless communications using Wi-Fi technology (e.g., a frequency band of 2.4 GHZ, corresponding to a wavelength of about 12 cm, or a frequency band of 5.8 GHZ, corresponding to a wavelength of about 5 cm). For example, the RF device 2500 may be included in a Wi-Fi-enabled device such as a desktop, a laptop, a video game console, a smart phone, a tablet, a smart TV, a digital audio player, a car, a printer, etc. In some implementations, a Wi-Fi-enabled device may be a node (e.g., a smart sensor) in a smart system configured to communicate data with other nodes. In another example, the RF device 2500 may be used for wireless communications using Bluetooth technology (e.g., a frequency band from about 2.4 to about 2.485 GHZ, corresponding to a wavelength of about 12 cm). In other embodiments, the RF device 2500 may be used for transmitting and/or receiving RF signals for purposes other than communication (e.g., in an automotive radar system, or in medical applications such as magnetic resonance imaging (MRI)).

In various embodiments, the RF device 2500 may be included in frequency-division duplex (FDD) or time-domain duplex (TDD) variants of frequency allocations that may be used in a cellular network. In an FDD system, the uplink (i.e., RF signals transmitted from the UE devices to a BS) and the downlink (i.e., RF signals transmitted from the BS to the US devices) may use separate frequency bands at the same time. In a TDD system, the uplink and the downlink may use the same frequencies but at different times.

A number of components are illustrated in FIG. 23 as included in the RF device 2500, but any one or more of these components may be omitted or duplicated, as suitable for the application. For example, in some embodiments, the RF device 2500 may be an RF device supporting both of wireless transmission and reception of RF signals (e.g., an RF transceiver), in which case it may include both the components of what is referred to herein as a transmit (TX) path and the components of what is referred to herein as a receive (RX) path. However, in other embodiments, the RF device 2500 may be an RF device supporting only wireless reception (e.g., an RF receiver), in which case it may include the components of the RX path, but not the components of the TX path; or the RF device 2500 may be an RF device supporting only wireless transmission (e.g., an RF transmitter), in which case it may include the components of the TX path, but not the components of the RX path.

In some embodiments, some or all of the components included in the RF device 2500 may be attached to one or more motherboards. In various embodiments, the RF device 2500 may not include one or more of the components illustrated in FIG. 23, but the RF device 2500 may include interface circuitry for coupling to the one or more components. For example, the RF device 2500 may not include an antenna 2502, but may include antenna interface circuitry (e.g., a matching circuitry, a connector and driver circuitry) to which an antenna 2502 may be coupled. In another set of examples, the RF device 2500 may not include a digital processing unit 2508 or a local oscillator 2506, but may include device interface circuitry (e.g., connectors and supporting circuitry) to which a digital processing unit 2508 or a local oscillator 2506 may be coupled.

As shown in FIG. 23, the RF device 2500 may include an antenna 2502, a duplexer 2504, a local oscillator 2506, and a digital processing unit 2508. As also shown in FIG. 23, the RF device 2500 may include an RX path that may include an RX path amplifier 2512 (which may be coupled to any of the antenna modules 100 disclosed herein), an RX path pre-mix filter 2514, a RX path mixer 2516, an RX path post-mix filter 2518, and an analog-to-digital converter (ADC) 2520. As further shown in FIG. 23, the RF device 2500 may include a TX path that may include a TX path amplifier 2522 (which may be coupled to any of the antenna modules 100 disclosed herein), a TX path post-mix filter 2524, a TX path mixer 2526, a TX path pre-mix filter 2528, and a digital-to-analog converter (DAC) 2530. Still further, the RF device 2500 may further include an impedance tuner 2532, an RF switch 2534, and control logic 2536. In various embodiments, the RF device 2500 may include multiple instances of any of the components shown in FIG. 23. In some embodiments, the RX path amplifier 2512, the TX path amplifier 2522, the duplexer 2504, and the RF switch 2534 may be considered to form, or be a part of, an RF front-end (FE) of the RF device 2500. In some embodiments, the RX path amplifier 2512, the TX path amplifier 2522, the duplexer 2504, and the RF switch 2534 may be considered to form, or be a part of, an RF FE of the RF device 2500. In some embodiments, the RX path mixer 2516 and the TX path mixer 2526 (possibly with their associated pre-mix and post-mix filters shown in FIG. 23) may be considered to form, or be a part of, an RF transceiver of the RF device 2500 (or of an RF receiver or an RF transmitter if only RX path or TX path components, respectively, are included in the RF device 2500). In some embodiments, the RF device 2500 may further include one or more control logic elements/circuits, shown in FIG. 23 as control logic 2536 (providing, for example, an RF FE control interface). The control logic 2536 may be used to enhance control of complex RF system environment, support implementation of envelope tracking techniques, reduce dissipated power, etc.

The antenna 2502 may be configured to wirelessly transmit and/or receive RF signals in accordance with any wireless standards or protocols, e.g., Wi-Fi, LTE, or GSM, as well as any other wireless protocols that are designated as 3G, 4G, 5G, and beyond. If the RF device 2500 is an FDD transceiver, the antenna 2502 may be configured for concurrent reception and transmission of communication signals in separate, e.g., non-overlapping and non-continuous, bands of frequencies, e.g., in bands having a separation of, e.g., 20 MHz from one another. If the RF device 2500 is a TDD transceiver, the antenna 2502 may be configured for sequential reception and transmission of communication signals in bands of frequencies that may be the same or overlapping for TX and RX paths. In some embodiments, the RF device 2500 may be a multi-band RF device, in which case the antenna 2502 may be configured for concurrent reception of signals having multiple RF components in separate frequency bands and/or configured for concurrent transmission of signals having multiple RF components in separate frequency bands. In such embodiments, the antenna 2502 may be a single wide-band antenna or a plurality of band-specific antennas (e.g., a plurality of antennas each configured to receive and/or transmit signals in a specific band of frequencies). In various embodiments, the antenna 2502 may include a plurality of antenna units, e.g., a plurality of antenna units forming a phased antenna array (i.e., a communication system or an array of antennas that may use a plurality of antenna units and phase shifting to transmit and receive RF signals). Compared to a single antenna system, a phased antenna array may offer advantages such as increased gain, ability of directional steering, and simultaneous communication. In some embodiments, the RF device 2500 may include more than one antenna 2502 to implement antenna diversity. In some such embodiments, the RF switch 2534 may be deployed to switch between different antennas.

An output of the antenna 2502 may be coupled to the input of the duplexer 2504. The duplexer 2504 may be any suitable component configured for filtering multiple signals to allow for bidirectional communication over a single path between the duplexer 2504 and the antenna 2502. The duplexer 2504 may be configured for providing RX signals to the RX path of the RF device 2500 and for receiving TX signals from the TX path of the RF device 2500.

The RF device 2500 may include one or more local oscillators 2506, configured to provide local oscillator signals that may be used for downconversion of the RF signals received by the antenna 2502 and/or upconversion of the signals to be transmitted by the antenna 2502.

The RF device 2500 may include the digital processing unit 2508, which may include one or more processing devices. In some embodiments, the digital processing unit 2508 may be implemented as the processing device 1802 of FIG. 22, descriptions of which are provided above. The digital processing unit 2508 may be configured to perform various functions related to digital processing of the RX and/or TX signals. Examples of such functions include, but are not limited to, decimation/downsampling, error correction, digital downconversion or upconversion, DC offset cancellation, automatic gain control, etc. Although not shown in FIG. 23, in some embodiments, the RF device 2500 may further include a memory device (e.g., the memory device 1804 described above with reference to FIG. 22) configured to cooperate with the digital processing unit 2508.

Turning to the details of the RX path that may be included in the RF device 2500, the RX path amplifier 2512 may include a low-noise amplifier (LNA). An input of the RX path amplifier 2512 may be coupled to an antenna port (not shown) of the antenna 2502, e.g., via the duplexer 2504. The RX path amplifier 2512 may amplify the RF signals received by the antenna 2502.

An output of the RX path amplifier 2512 may be coupled to an input of the RX path pre-mix filter 2514, which may be a harmonic or band-pass (e.g., low-pass) filter, configured to filter received RF signals that have been amplified by the RX path amplifier 2512.

An output of the RX path pre-mix filter 2514 may be coupled to an input of the RX path mixer 2516, also referred to as a downconverter. The RX path mixer 2516 may include two inputs and one output. A first input may be configured to receive the RX signals, which may be current signals, indicative of the signals received by the antenna 2502 (e.g., the first input may receive the output of the RX path pre-mix filter 2514). A second input may be configured to receive local oscillator signals from one of the local oscillators 2506. The RX path mixer 2516 may then mix the signals received at its two inputs to generate a downconverted RX signal, provided at an output of the RX path mixer 2516. As used herein, downconversion refers to a process of mixing a received RF signal with a local oscillator signal to generate a signal of a lower frequency. In particular, the RX path mixer (e.g., downconverter) 2516 may be configured to generate the sum and/or the difference frequency at the output port when two input frequencies are provided at the two input ports. In some embodiments, the RF device 2500 may implement a direct-conversion receiver (DCR), also known as homodyne, synchrodyne, or zero-intermediate frequency (IF) receiver, in which case the RX path mixer 2516 may be configured to demodulate the incoming radio signals using local oscillator signals whose frequency is identical to, or very close to the carrier frequency of the radio signal. In other embodiments, the RF device 2500 may make use of downconversion to an IF. IFs may be used in superheterodyne radio receivers, in which a received RF signal is shifted to an IF, before the final detection of the information in the received signal is done. Conversion to an IF may be useful for several reasons. For example, when several stages of filters are used, they can all be set to a fixed frequency, which makes them easier to build and to tune. In some embodiments, the RX path mixer 2516 may include several such stages of IF conversion.

Although a single RX path mixer 2516 is shown in the RX path of FIG. 23, in some embodiments, the RX path mixer 2516 may be implemented as a quadrature downconverter, in which case it would include a first RX path mixer and a second RX path mixer. The first RX path mixer may be configured for performing downconversion to generate an in-phase (I) downconverted RX signal by mixing the RX signal received by the antenna 2502 and an in-phase component of the local oscillator signal provided by the local oscillator 2506. The second RX path mixer may be configured for performing downconversion to generate a quadrature (Q) downconverted RX signal by mixing the RX signal received by the antenna 2502 and a quadrature component of the local oscillator signal provided by the local oscillator 2506 (the quadrature component is a component that is offset, in phase, from the in-phase component of the local oscillator signal by 90 degrees). The output of the first RX path mixer may be provided to a l-signal path, and the output of the second RX path mixer may be provided to a Q-signal path, which may be substantially 90 degrees out of phase with the I-signal path.

The output of the RX path mixer 2516 may, optionally, be coupled to the RX path post-mix filter 2518, which may be low-pass filters. In case the RX path mixer 2516 is a quadrature mixer that implements the first and second mixers as described above, the in-phase and quadrature components provided at the outputs of the first and second mixers respectively may be coupled to respective individual first and second RX path post-mix filters included in the RX path post-mix filter 2518.

The ADC 2520 may be configured to convert the mixed RX signals from the RX path mixer 2516 from the analog to the digital domain. The ADC 2520 may be a quadrature ADC that, similar to the RX path mixer 2516, may include two ADCs, configured to digitize the downconverted RX path signals separated in in-phase and quadrature components. The output of the ADC 2520 may be provided to the digital processing unit 2508, configured to perform various functions related to digital processing of the RX signals so that information encoded in the RX signals can be extracted.

Turning to the details of the TX path that may be included in the RF device 2500, the digital signal to later be transmitted (TX signal) by the antenna 2502 may be provided, from the digital processing unit 2508, to the DAC 2530. Similar to the ADC 2520, the DAC 2530 may include two DACs, configured to convert, respectively, digital I- and Q-path TX signal components to analog form.

Optionally, the output of the DAC 2530 may be coupled to the TX path pre-mix filter 2528, which may be a band-pass (e.g., low-pass) filter (or a pair of band-pass, e.g., low-pass, filters, in case of quadrature processing) configured to filter out, from the analog TX signals output by the DAC 2530, the signal components outside of the desired band. The digital TX signals may then be provided to the TX path mixer 2526, which may also be referred to as an upconverter. Similar to the RX path mixer 2516, the TX path mixer 2526 may include a pair of TX path mixers, for in-phase and quadrature component mixing. Similar to the first and second RX path mixers that may be included in the RX path, each of the TX path mixers of the TX path mixer 2526 may include two inputs and one output. A first input may receive the TX signal components, converted to the analog form by the respective DAC 2530, which are to be upconverted to generate RF signals to be transmitted. The first TX path mixer may generate an in-phase (I) upconverted signal by mixing the TX signal component converted to analog form by the DAC 2530 with the in-phase component of the TX path local oscillator signal provided from the local oscillator 2506 (in various embodiments, the local oscillator 2506 may include a plurality of different local oscillators, or be configured to provide different local oscillator frequencies for the RX path mixer 2516 in the RX path and the TX path mixer 2526 in the TX path). The second TX path mixer may generate a quadrature phase (Q) upconverted signal by mixing the TX signal component converted to analog form by the DAC 2530 with the quadrature component of the TX path local oscillator signal. The output of the second TX path mixer may be added to the output of the first TX path mixer to create a real RF signal. A second input of each of the TX path mixers may be coupled the local oscillator 2506.

Optionally, the RF device 2500 may include the TX path post-mix filter 2524, configured to filter the output of the TX path mixer 2526.

As noted above, the TX path amplifier 2522 may be a power amplifier, configured to amplify the upconverted RF signal before providing it to the antenna 2502 for transmission.

In various embodiments, any of the RX path pre-mix filter 2514, the RX path post-mix filter 2518, the TX path post-mix filter 2524, and the TX path pre-mix filter 2528 may be implemented as RF filters. In some embodiments, each of such RF filters may include one or more resonators (e.g., AWRs, film bulk acoustic resonators (FBARs), Lamb wave resonators, and/or contour-wave resonators), arranged in any suitable manner (e.g., in a ladder configuration). In some embodiments, an RF filter may be implemented as a plurality of RF filters, or a filter bank. A filter bank may include a plurality of RF resonators that may be coupled to a switch (e. g., the RF switch 2534) configured to selectively switch any one of the plurality of RF resonators on and off (e.g., activate any one of the plurality of RF resonators), in order to achieve desired filtering characteristics of the filter bank (e.g., in order to program the filter bank). For example, such a filter bank may be used to switch between different RF frequency ranges when the RF device 2500 is, or is included in, a BS or in a UE device. In another example, such a filter bank may be programmable to suppress TX leakage on the different duplex distances.

The impedance tuner 2532 may include any suitable circuitry, configured to match the input and output impedances of the different RF circuitries to minimize signal losses in the RF device 2500. For example, the impedance tuner 2532 may include an antenna impedance tuner. Being able to tune the impedance of the antenna 2502 may be particularly advantageous because antenna's impedance is a function of the environment that the RF device 2500 is in, e.g., antenna's impedance changes depending on, e.g., if the antenna is held in a hand, placed on a car roof, etc.

As described above, the RF switch 2534 may be a device configured to route high-frequency signals through transmission paths in order to selectively switch between a plurality of instances of any one of the components shown in FIG. 23 (e.g., to achieve desired behavior and characteristics of the RF device 2500). In some embodiments, an RF switch 2534 may be used to switch between different antennas 2502. In other embodiments, an RF switch may be used to switch between a plurality of RF resonators (e.g., by selectively switching RF resonators on and off) of any of the filters included in the RF device 2500. Typically, an RF system may include a plurality of such RF switches.

The RF device 2500 provides a simplified version and, in further embodiments, other components not specifically shown in FIG. 23 may be included. For example, the RX path of the RF device 2500 may include a current-to-voltage amplifier between the RX path mixer 2516 and the ADC 2520, which may be configured to amplify and convert the downconverted signals to voltage signals. In another example, the RX path of the RF device 2500 may include a balun transformer for generating balanced signals. In yet another example, the RF device 2500 may further include a clock generator, which may include a suitable phase-lock loop (PLL), configured to receive a reference clock signal and use it to generate a different clock signal that may then be used for timing the operation of the ADC 2520, the DAC 2530, and/or that may also be used by the local oscillator 2506 to generate the local oscillator signals to be used in the RX path or the TX path.

The following paragraphs provide examples of various ones of the embodiments disclosed herein.

Example 1 provides an antenna module that includes a plurality of antenna units provided over the antenna unit support, and a plurality of ICs communicatively coupled to individual ones of the antenna units. The ICs are arranged in two or more subsets of one or more ICs in each subset, where an individual IC belongs to only one subset of the two or more subsets (i.e., the two or more subsets are what is referred to in mathematics as “non-overlapping subsets”), different subsets are in different layers with respect to the antenna unit support (i.e., the subsets of ICs are stacked over one another), and an average pitch of projections of all of the ICs of the plurality of ICs onto a plane parallel to the antenna unit support is substantially equal to or smaller than an average pitch of the antenna units. When the average pitch of the antenna units is a dimension along an axis in the plane, and an average dimension of an individual IC along the axis is larger than the average pitch of the antenna units, arranging the ICs in two or more subsets in different layers with respect to the antenna unit support means that at least one of the ICs of one subset (e.g., all of the ICs in one subset) partially overlaps with at least one of the ICs of another subset. As used herein, the term “pitch” refers to a center-to-center distance; the term “average” refers to a result obtained by adding together pitches of different nearest-neighbor projections and then dividing the sum by the total number of the pitches added together; and the term “substantially” refers to being within +/−20%, e.g., within +/−5% or within +/−2%, of a target (where the “target” in this context may be that the average pitch of the projections of the ICs is equal to the average pitch of the projections of the antenna units).

Example 2 provides the antenna module according to example 1, where the average pitch of the antenna units is a dimension along an axis in the plane, and where an average dimension of the individual IC along the axis is larger than the average pitch of the antenna units.

Example 3 provides the antenna module according to examples 1 or 2, where the two or more subsets include two subsets, the projections of the ICs are in a linear array (i.e., arranged along a line, e.g., a straight line) of the projections, and the antenna units are in a linear array of the antenna units.

Example 4 provides the antenna module according to examples 1 or 2, where the two or more subsets include four subsets, the projections of the ICs are in a two-dimensional array of the projections, and the antenna units are in a two-dimensional array of the antenna units.

Example 5 provides the antenna module according to any one of examples 1-5, further including a plurality of dies, where individual ICs are on different dies of the plurality of dies in a one-to-one correspondence (i.e., each IC is on one and only one die and each die includes one and only one IC of the plurality of ICs).

Example 6 provides the antenna module according to any one of examples 1-5, further including a plurality of dies, where at least one die of the plurality of dies includes two or more ICs of the plurality of ICs.

Example 7 provides the antenna module according to example 6, where the two or more ICs are ICs of one of the two or more subsets.

Example 8 provides the antenna module according to any one of examples 5-7, further including a die-to-die interconnect between a first die and a second die, where the first die includes an IC of a first subset of the two or more subsets, and the second die includes an IC of a second subset of the two or more subsets.

Example 9 provides the antenna module according to example 8, where the die-to-die interconnect includes a solder bump (e.g., a micro-bump).

Example 10 provides the antenna module according to example 8, where the die-to-die interconnect includes a direct bonding interconnect.

Example 11 provides the antenna module according to example 8, where the die-to-die interconnect includes a hybrid bonding interconnect.

Example 12 provides the antenna module according to any one of the preceding examples, where individual ICs are communicatively coupled to individual antenna units in a one-to-one correspondence (i.e., each IC is associated with one and only one antenna unit and each antenna unit is associated with one and only one IC).

Example 13 provides the antenna module according to any one of the preceding examples, where an individual antenna unit of the plurality of antenna units is one of an antenna patch or a slanted dipole antenna.

Example 14 provides the antenna module according to any one of the preceding examples, where the antenna unit support includes a PCB.

Example 15 provides an antenna module that includes an antenna unit support; an array of antenna units provided over the antenna unit support, the array including a first antenna unit and a second antenna unit; a first die including an IC to control the first antenna unit; and a second die including an IC to control the second antenna unit, where a width of the first die or the second die is larger than a distance between the first antenna unit and the second antenna unit, the first die is at a first distance from the antenna unit support, the second die is at a second distance from the antenna unit support (the second distance different from the first distance), and a projection of the first die onto a plane parallel to the antenna unit support partially overlaps a projection of the second die onto the plane.

Example 16 provides the antenna module according to example 15, where the array further includes a third antenna unit and a fourth antenna unit, and the antenna module further includes a third die including an IC to control the third antenna unit and a fourth die including an IC to control the fourth antenna unit, where the third die is at a third distance from the antenna unit support (the third distance different from the first and second distances), the fourth die is at a fourth distance from the antenna unit support (the fourth distance different from the first, second, and third distances), and the projection of the first die onto the plane partially overlaps a projection of the third die onto the plane and a projection of the fourth die onto the plane.

Example 17 provides the antenna module according to examples 15 or 16, where a center-to-center distance between the projection of the first die onto the plane and the projection of the second die onto the plane is substantially equal to a center-to-center distance between the first antenna unit and the second antenna unit.

Example 18 provides the antenna module according to any one of examples 15-17, where the first antenna unit and the second antenna unit are nearest-neighbor antenna units of the array.

Example 19 provides a communication device that includes a display; a back cover; and an antenna module between the display and the back cover, the antenna module including antenna units and ICs including at least portions of RF transceiver circuitry to control operation of the antenna units, where the ICs are arranged in two or more different layers below a layer with the antenna units, and an average center-to-center distance between nearest projections of the ICs on a plane parallel to the display is substantially equal to an average center-to-center distance between nearest projections of the antenna units onto the plane.

Example 20 provides the communication device according to example 19, where the average center-to-center distance between the nearest projections of the antenna units onto the plane is larger than a width of at least one of the ICs.

Example 21 provides the communication device according to examples 19 or 20, where an individual layer of the two or more layers includes a subset of two or more of the ICs arranged on one or more dies.

Example 22 provides the communication device according to any one of examples 19-21, where an individual antenna unit of the antenna units is a millimeter wave antenna unit, a sub-THz antenna unit, or a THz antenna unit.

Example 23 provides the communication device according to any one of examples 19-22, where the communication device is a handheld communication device.

Example 24 provides the communication device according to any one of examples 19-22, where the communication device is a BS.

Example 25 provides an electronic assembly that includes an IC component; and an antenna module coupled to the IC component, where the antenna module is an antenna module according to any one of the preceding examples, and/or is a part of the communication device according to any one of the preceding examples.

Example 26 provides the electronic assembly according to example 25, where the IC component is one of a package substrate, a circuit board, an interposer, or a die.

Example 27 provides the electronic assembly according to examples 25 or 26, further including interconnects between the antenna module and the IC component.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An antenna module, comprising:
an antenna unit support;
a plurality of antenna units over or at least partially in the antenna unit support; and
a plurality of integrated circuits (ICs),
wherein:
the plurality of ICs includes two or more subsets of one or more ICs,
an individual IC of the plurality of ICs belongs to only one subset of the two or more subsets,
different subsets of the two or more subsets are in different layers with respect to the antenna unit support, and
an average pitch of projections of the ICs onto a plane parallel to the antenna unit support is substantially equal to or smaller than an average pitch of projections of the antenna units onto the plane.

2. The antenna module according to claim 1, wherein the average pitch of the antenna units is a dimension along an axis in the plane, and wherein an average dimension of the individual IC along the axis is larger than the average pitch of the antenna units.

3. The antenna module according to claim 1, wherein:
the two or more subsets include two subsets,
the projections of the ICs are in a linear array of the projections, and
the antenna units are in a linear array of the antenna units.

4. The antenna module according to claim 1, wherein:
the two or more subsets include four subsets,
the projections of the ICs are in a two-dimensional array of the projections, and
the antenna units are in a two-dimensional array of the antenna units.

5. The antenna module according to claim 1, further comprising a plurality of dies, wherein individual ICs are on different dies of the plurality of dies.

6. The antenna module according to claim 1, further comprising a plurality of dies, wherein at least one die of the plurality of dies includes two or more ICs of the plurality of ICs.

7. The antenna module according to claim 6, wherein the two or more ICs are ICs of one of the two or more subsets.

8. The antenna module according to claim 1, further comprising a first die, a second die, and a die-to-die interconnect between the first die and the second die, wherein the first die includes an IC of a first subset of the two or more subsets, and the second die includes an IC of a second subset of the two or more subsets.

9. The antenna module according to claim 8, wherein the die-to-die interconnect includes a solder bump.

10. The antenna module according to claim 8, wherein the die-to-die interconnect includes a direct bonding interconnect.

11. The antenna module according to claim 8, wherein the die-to-die interconnect includes a hybrid bonding interconnect.

12. The antenna module according to claim 1, wherein individual ICs are communicatively coupled to individual antenna units in a one-to-one correspondence.

13. The antenna module according to claim 1, wherein an individual antenna unit of the plurality of antenna units is one of an antenna patch or a slanted dipole antenna.

14. The antenna module according to claim 1, wherein the antenna unit support includes a printed circuit board.

15. An antenna module, comprising:
an antenna unit support;
an array of antenna units over the antenna unit support, the array including a first antenna unit and a second antenna unit;
a first die comprising an integrated circuit (IC) to control the first antenna unit; and
a second die comprising an IC to control the second antenna unit,
wherein:
a width of the first die or the second die is larger than a distance between the first antenna unit and the second antenna unit,
the first die is at a first distance from the antenna unit support,
the second die is at a second distance from the antenna unit support, and
a projection of the first die onto a plane parallel to the antenna unit support partially overlaps a projection of the second die onto the plane.

16. The antenna module according to claim 15, wherein the array further includes a third antenna unit and a fourth antenna unit, and the antenna module further includes a third die comprising an IC to control the third antenna unit and a fourth die comprising an IC to control the fourth antenna unit, wherein:
the third die is at a third distance from the antenna unit support,
the fourth die is at a fourth distance from the antenna unit support, and
the projection of the first die onto the plane partially overlaps a projection of the third die onto the plane and a projection of the fourth die onto the plane.

17. The antenna module according to claim 15, wherein a center-to-center distance between the projection of the first die onto the plane and the projection of the second die onto the plane is substantially equal to a center-to-center distance between the first antenna unit and the second antenna unit.

18. The antenna module according to claim 15, wherein the first antenna unit and the second antenna unit are nearest-neighbor antenna units of the array.

19. A communication device, comprising:
a display;
a back cover; and
an antenna module between the display and the back cover, the antenna module comprising antenna units and integrated circuits (ICs) comprising at least portions of radio frequency transceiver circuitry to control operation of the antenna units,
wherein the ICs are in two or more layers below a layer with the antenna units, and an average center-to-center distance between nearest projections of the ICs on a plane parallel to the display is substantially equal to an average center-to-center distance between nearest projections of the antenna units onto the plane.

20. The communication device according to claim 19, wherein the average center-to-center distance between nearest projections of the antenna units onto the plane is larger than a width of at least one of the ICs.
